(19) United States
(12) Patent Application Publication
(10) Pub. No.: US 2009/0231351 A1
(43) Pub. Date: Sep. 17, 2009

(54) SEMICONDUCTOR MEMORY DEVICE HAVING DATA ROTATION/INTERLEAVE FUNCTION

(75) Inventor: Keiji Kawashima, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Osaka (JP)

(21) Appl. No.: 11/996,398

(22) PCT Filed: Jul. 21, 2006
(86) PCT No.: PCT/JP2006/314522

§ 371 Date: Jan. 22, 2008

(30) Foreign Application Priority Data
Jul. 21, 2005 (JP) 2005-211520

(51) Int. Cl. G09G 5/36; G11C 17/00; G11C 7/10

(52) U.S. Cl. 345/560; 365/94; 365/189.05

(57) ABSTRACT

An object of the present invention is to provide a memory device and a memory application device which can reduce memories and reduce burden on processings by reading out predetermined bit data stored in plural memory addresses as data output from the memory device.

The memory device of the present invention is provided with multiplexers (30₁, . . . , 3n−1ₙ₋₂) which can selectively output data in memory cells (0₀₀, . . . , n−1ₘ₋₁ₙ₋₁) outputted by buffer circuits (20₀, . . . , 2n−1ₙ₋₁) one-bit by one-bit from each of memory cell arrays (1₀ to 1ₙ₋₁) or n bits from one memory cell array.

### TECHNICAL FIELD

The present invention relates to a memory device and a memory application device, and more particularly, to a memory device which can read out predetermined bit data stored in plural memory addresses as its data outputs by accessing predetermined memory addresses, and a memory application apparatus including a memory device of this type.

### BACKGROUND ART

Conventionally, memory devices have been used as information storage means in system constructions of semiconductor integrated circuits.

The memory devices include a read-only memory (hereinafter referred to as a ROM) from which information data that have been physically embedded therein during its fabrication process can be arbitrarily read out as needed, and a read/write memory (hereinafter referred to as a RAM) from which information data that are temporarily stored therein can be read out as needed.

When performing reading or writing of information data from/in such conventional memory device, an address signal that specifies a storage area is input to the memory device, whereby the information data is outputted from a memory cell that is specified by the input memory address in the case of reading, while the information data inputted to the memory device is input to a memory cell that is specified by the memory address in the case of writing. Thereby, a memory application device having a memory device of this type is operated.

FIG. 17 is a block diagram illustrating the construction of a ROM as an example of a conventional memory device.

With reference to FIG. 17, 1600 denotes a memory block comprising memory cell arrays 1601, 1602, . . . , 1603, and 1601 denotes a memory cell array which stores only data of bit 0 when the number of bits of information data to be stored in this memory device is n (n: positive integer).

Likewise, 1602, . . . , 1603 also denote memory cell arrays which store only data of bit 1, . . . , bit n−1, respectively. 1604, 1605, . . . , 1606 denote word selection signals, 1607, 1608, . . . , 1609 denote column selection signals, and 1610, 1611, . . . , 1612 denote memory cells in the memory cell array 1601 which are selected by the word selection signal 1604.

Likewise, 1613, 1614, . . . , 1615, and 1616, 1617, . . . , 1618 denote memory cells in the memory cell arrays 1602 and 1603 which are selected by the word selection signal 1604, respectively. With respect to the memory cells in the respective memory cell arrays, reference numerals are given to only those selected by the word selection signal 1604 for convenience in illustration.

Further, the memory cells in the respective memory cell arrays are connected with each other in the horizontal direction by word lines (not shown) and in the vertical direction by column lines (not shown) in FIG. 17.

In FIG. 17, 1619, 1620, . . . , 1621, and 1622, 1623, . . . , 1624, and 1625, 1626, . . . , 1627 denote buffer circuits having sense amplifier functions for amplifying the outputs of the memory cell arrays 1601, 1602, and 1603, respectively, as well as gate functions for controlling output/non-output of the amplification results by the column selection signals.

1628 denotes a data output of bit 0 when the number of bits of the information data is n, and it is obtained by unifying the outputs of the buffer circuits 1619, 1620, . . . , 1621 by wired-OR.

Likewise, 1629, . . . , 1630 denote data outputs of bit 1, . . . , bit n−1 when the number of bits of the information data is n, which are obtained by unifying the outputs of the buffer circuits 1622, 1623, . . . , 1624 and the outputs of the buffer circuits 1625, 1626, . . . , 1627 by wired-OR, respectively.

1631 denotes an address input, 1632 denotes an address decoder, 1633 denotes a word decoder, 1634 denotes a column decoder, and 1635 denotes a memory device comprising the respective constituents mentioned above.

In such conventional memory device, when executing readout of information data, a predetermined address input 1631 which specifies an area where the information data is stored is input to the address decoder 1632 in the memory device 1635, and a signal indicating a higher order address in the address input 1631 is input to the word decoder 1633 while a signal indicating a lower order address is input to the column decoder 1634, respectively.

The word decoder 1633 changes a word selection signal corresponding to the higher order address of the address input 1631 into the memory cell selection state, and changes the other word selection signals into the memory cell non-selection states.

Further, the column decoder 1634 changes a column selection signal corresponding to the lower order address of the address input 1631 into the memory cell selection state, and changes the other column selection signals to the memory cell non-selection states.

The output of the memory cell having both of the word selection signal and the column selection signal being in the selection states is outputted as a data output from the buffer circuit corresponding to the relevant memory cell array.

Hereinafter, an operation performed when an address 0 is input to the address input 1631 will be described.

Assuming that the memory cell selection state is H level, at this time, for example, the word selection signal changes only the word selection signal 1604 corresponding to the address 0 into H level, and changes the other word selection signals 1605, . . . , 1606 into L level in the non-selection state. Thereby, the memory cells 1610, 1611, . . . , 1612, 1613, 1614, . . . , 1615, . . . , 1616, 1617, . . . , 1618 are selected.

Likewise, assuming that the memory cell selection state is H level, for example, the column selection signal changes only the column selection signal 1607 corresponding to the address 0 into H level, and changes the other column selection signals 1608, . . . , 1609 into L level in the non-selection state.

Thereby, only the outputs of the buffer circuits 1619, 1622, . . . , 1625 become effective while the outputs of the other buffer circuits 1620, . . . , 1621, 1623, . . . , 1624, 1626, . . . , 1627 become ineffective, whereby the information data stored in the memory cell 1610 are outputted as a data output 1628 of bit 0.

Likewise, the information data stored in the memory cells 1613, . . . , 1616 are outputted as data outputs 1629, . . . , 1630 of bit 1, . . . , bit n−1, and thereby information data having n bits in total are outputted (for example, refer to Patent Document 1).

By the way, there is a display control device as an example of a memory application device using such conventional memory device. FIG. 18 is a block diagram illustrating the construction of a display control device as an example of a conventional memory application device.

With reference to FIG. 18, the display control device 1700 includes a display operation control circuit 1703 which externally receives a horizontal sync signal 1701 and a vertical sync signal 1702 which indicate a display timing to a display 1711, and controls a display operation at a predetermined position on a screen, and a display data shift register 1708 which receives display data 1707 from the display operation control circuit 1703, and shift-outputs a display signal 1710 according to a display dot clock 1709 that is externally input.

The display control device 1700 thus constituted image-displays display font data 1706 that are stored in a display font ROM 1705 onto the display 1711.

The display font ROM 1705 outputs the display font data 1706 to the display operation control circuit 1703 on the basis of a display font address 1704 outputted from the display operation control circuit 1703, and the display operation control circuit 1703 outputs the display font data 1706 to the display data shift register 1708 as the display data 1707 in a data format and at a timing for performing display operation.

In the conventional display control device constituted as described, when performing display operation, font data comprising horizontal n dots×vertical m dots (m,n: positive integers) as shown in FIG. 19(a) are stored in the display font ROM 1705, and the font data are stored by every horizontal n dots in the display data shift register 1708. These font data are outputted bit by bit in synchronization with the display dot clock 1709 to the display 1711, whereby the font data of n bits corresponding to one horizontal row are read out for every horizontal scanning of the TV screen as shown in FIG. 19(b), and displayed on the TV screen. This scanning may be either progressive or interlace.

FIG. 19(c) shows a logical address space image in the state where the font data are stored in the display font ROM 1705. In the display font ROM 1705, font data of n bits to be read out for each horizontal scanning are successively stored in continuous logical address spaces.

More specifically, assuming that the word addresses of the font data of n×m dots in FIG. 19(a) are 0, 1, . . . , m−1 and the column addresses thereof are 0, 1, . . . , n−1, the font data are stored in the column direction for each of the row addresses 0, 1, . . . , m−1 as shown in FIG. 19(c).

By the way, as shown in FIG. 20, when the display 1711 is used for an application in which the display is rotated rightward (rotated at 90° in the clockwise direction) from its original display position, i.e., from the state where it is set horizontally long (refer to FIG. 20(a)) to perform vertically long display (refer to FIG. 20(b)), the font data on the TV screen (refer to FIG. 20(c)) are also displayed rotated at 90° in the clockwise direction like the display 1711 (refer to FIG. 20(d)).

FIGS. 20(c) and 20(d) show examples of font data, wherein a number “1” is displayed with font data of 4×4 dots to simplify the description.

Therefore, in the display font ROM 1705, font data that are previously rotated at 90° in accordance with the rotation direction of the display are prepared as well as normal font data, i.e., fonts that are displayed upright in the state where the display is arranged horizontally long, and either of these two kinds of font data is selected so that, even after the display is rotated from its horizontally long state to vertically long state, the fonts can be displayed normally, i.e., in its upright state independently from this rotation (for example, refer to Patent Document 2).

Further, when the font data is displayed on the TV screen with its color representation being gradation colors, a case where 1 dot of the font data is displayed with 4-bit data will be described as an example.

As shown in FIG. 21(a), assuming that an aggregate of font data which are constituted by only bits in the same bit position of 4-bit data constituting each dot is a layer, for example, an aggregate of font data constituted by only the 0th bits of the 4-bit data is layer 0, an aggregate of only the 1st bits is layer 1, an aggregate of only the 2nd bits is a layer 2, and an aggregate of only the 3rd bits is a layer 3, and all of these data are previously stored in the display font ROM 1705 as one font data.

When performing display operation, as shown in FIG. 21(b), the font data of n bits (n: positive integer) corresponding to one horizontal row are read out from layer 0 to layer 3 by every horizontal scanning on the TV screen, and these font data are simultaneously displayed as display data, whereby the font data having color representation of 4 bits for each dot are displayed.

Therefore, the font data are stored in the display font ROM 1705 such that the data from layer 0 to layer 3 are stored in continuous logical address space for each horizontal scanning unit. An image of the logical address space is shown in FIG. 22.

In the logical address space, since the font data are stored over plural addresses, the logical address space in the depth direction is also accessed, not only that the data are read out in the row direction and the column direction to access one information data like the ordinary memory access, thereby realizing display of the font data having color representation of gradation colors (for example, refer to Patent Document 3).

On the other hand, there is a transmission/reception system used for transmission of digital data as another example of a memory application device using the conventional memory device. FIG. 23 is a block diagram illustrating the construction of the transmission/reception system.

With reference to FIG. 23, the transmission/reception system comprises a transmitter 2100, a receiver 2106, and a transmission path 2105 for transmitting a signal from the transmitter 2100 to the receiver 2106. The transmitter 2100 comprises a processor 2101 performing control, a transmission data storage RAM 2102 for storing transmission data, an interleave memory 2103, and a transmission circuit 2104.

The processor 2101 stores transmission data to be transmitted in the transmission data storage RAM 2102, and reads out the data when transmission is performed. Then, in order to perform interleaving for rearranging the sequence of the transmission data to avoid data errors in the transmission step, the processor 2101 once stores the read transmission data in the interleave memory 2103, and reads out the transmission data having the bit sequence being rearranged by interleaving, and then transfers the read data to the transmission circuit 2104, whereby the data are transferred to the transmission path 2105 as transmission data.

Further, the receiver 2106 comprises a reception circuit 2107, a processor 2108 for performing control, a deinterleave memory 2109, and a reception data storage RAM 2110 for storing reception data, and the processor 2108 receives the transmission data from the transmission path 2105 by the reception circuit 2107 and stores the data in the deinterleave memory 2109.

The deinterleave memory 2109 uses the same memory as the interleave memory 2103 of the transmitter 2100, and the interleaved transmission data are stored in and read out from the deinterleave memory 2109, whereby the transmission data are rearranged to the bit sequence of the original transmission data.

The processor 2108 stores the data that are read out from the deinterleave memory 2109 into the reception data storage RAM 2110 as reception data.

An example of bit sequence rearrangement by the interleave memory 2103 will be described with reference to FIG. 24. In the transmission system where transmission data are constituted by 128 bits in total, when performing interleaving such that the transmission data are transmitted with skipping 16 bits from the beginning, FIG. 24(a) shows that the transmission data of 128 bits are continuous from head bit D0 to last bit D127.

When the transmission data are stored in and read out from the interleave memory 2103, the transmission data become as shown in FIG. 24 (b). That is, the head bit D16 is followed by, with 16 bits being skipped, D16, and the 8th bit D112 is followed by D1, and next D17, and thereafter, transmission data of similar sequence are generated up to D127, thereby realizing interleaving.

Further, it is possible to realize similar interleaving or deinterleaving by using an ordinary RAM or a logical operation function of a processor, without using the interleave memory 2103 or the deinterleave memory 2109. A flowchart in this case is shown in FIG. 25.

FIG. 25(a) is a flowchart illustrating the contents of interleaving. After a start process of performing initialization of read addresses (S11), data of 16 bits, i.e., 2 bytes as a rearrangement cycle are read out from the transmission data storage RAM 2102 (S12), and then only transmission bits are extracted by a bit shift operation function (S13) and a logic OR operation function (S14). These processes are repeated until transmission data of 8 bits are prepared (S15, S16).

When transmission data of 8 bits are prepared, the transmission data are transferred to the transmission circuit 2104 (S17), and while the transmission data are being transmitted, next transmission data are generated by similar processing. These processes are repeated by several hundreds of steps until all the transmission data are transferred (S18, S19).

Further, FIG. 25(b) is a flowchart illustrating the contents of deinterleaving. After a start process of performing initialization of read addresses (S21), the transmission data supplied from the reception circuit 2107 are once stored in the reception data storage RAM 2110 (S22), and data of 8 bits, i.e., 1 byte are read out (S23), and then only reception bits are extracted by a bit shift operation function (S24) and a logic OR operation function (S25). These processes are repeated until reception data of 16 bits are prepared (S26, S27).

When reception data of 16 bits are prepared, the reception data are stored in the reception data storage RAM 2110, and these processes are repeated by several hundreds of steps until rearrangement for all the reception data is completed (S28, S29).

Further, there is a processor system using a CPU as another example of a memory application device using the conventional memory device. FIG. 26 is a block diagram illustrating the construction of a processor system using a CPU as a conventional memory application device.

With reference to FIG. 26, a processor system using a CPU comprises a CPU 2400, an address bus 2401, a memory controller 2402, a program memory 2403, and chip select signals 2404, 2405, 2406, and 2407.

In order to execute a program, the CPU 2400 inputs the address bus 2401 into the program memory 2403, and reads a command code stored in the corresponding memory space. When executing plural kinds of programs, the memory space of the program memory 2403 is divided into bank areas, and the different programs are stored in the respective bank areas.

FIG. 26 shows an example where the memory space of the program memory 2403 is divided into four bank areas. The memory controller 2402 inputs the address bus 2401, and outputs, according to the memory space, the chip select signal 2404 for selecting the area of bank 0, the chip select signal 2405 for selecting the area of bank 1, the chip select signal 2406 for selecting the area of bank 2, and the chip select signal 2407 for selecting the area of bank 3.

The memory controller 2402 changes the chip select signal according to the area of the corresponding address bas 2401. It is possible to realize a system having plural memories in similar manner using this construction (for example, refer to Patent Document 5).

Patent Document 1: Japanese Published Patent Application No. Hei. 9-29389 (Page 9, FIG. 1)

Patent Document 2: Japanese Published Patent Application No. 2000-20046 (Page 4, FIG. 2)

Patent Document 3: Japanese Published Patent Application No. Hei. 11-7272 (Page 4, FIG. 1)

Patent Document 4: Japanese Published Patent Application No. Sho. 62-298077 (Page 3, FIG. 3)

Patent Document 5: Japanese Published Patent Application No. Hei. 7-200398 (Page 8, FIG. 1)

### DISCLOSURE OF THE INVENTION

### Problems to be Solved by the Invention

However, in the conventional memory device described above, readout of information data can be executed only in logical address units. So, in order to read out only predetermined bit data stored over plural addresses, information data to be read out must be previously stored in the memory device, or readout access to corresponding addresses must be performed for each address, thereby to extract predetermined bit data.

Further, in the display control device as the conventional memory application device, in order to perform correct display even when the device is used for an application where the display is rotated at 90° to be arranged vertically long, it is necessary to prepare font data which have previously been rotated in accordance with the rotation direction of the display in the display font ROM.

In this case, double amount of font data including those for normal display or triple amount of font data when considering rightward rotation and leftward rotation are required, and thereby the memory capacity of the display font ROM increases, resulting in a cause for an increase in area when the memory device is mounted on an integrated circuit.

Further, with respect to the font data for gradation color display, the area increases by two times, three times, and four times according to the gradation degree.

Although there is a means such as bit map display as another method of performing rotation display, this method needs a buffer memory for display, and there occurs a process of storing font data read out from the display font ROM into the buffer memory after rearranging the font data into a data sequence in its rotated state by using a processor or the like. Therefore, the burden on the processor increases in addition to an increase in the area of the buffer memory, resulting in an increase in the power consumption due to high-speed processing.

Further, in the transmission/reception system used for digital data transmission in the conventional memory application device, the memories for interleaving and deinterleaving are required in addition to the RAM for storing the transmission/reception data, resulting a cause for an increase in area when these memories are mounted on an integrated circuit. Further, both the memories for interleaving and deinterleaving also require the readout memory cell selection signals for all the memory cells besides the write selection signals according to the interleaving method, resulting in an increase in writing area.

Further, since the data sequences in the readout memory cells are fixed in the memories for interleaving and deinterleaving, these memories cannot be used as normal memories.

Further, when these processes are performed using an ordinary memory, a storage area for transmission data or reception data and an area for storing interleaved transmission data must be provided in one memory, which causes an increase in the memory area. Further, since logical operations for data rearrangement and data generation by a processor are required at a level of several hundreds of steps according to the amount of transmission data, the burden on the processor increases, resulting in an increase in the power consumption due to high-speed processing.

Further, in the processor system using a CPU as the conventional memory application device, when the processor system executes plural kinds of programs, logical areas of program memories must be secured for the respective programs, and thereby a memory capacity equivalent to the code size of the all programs is required, resulting in an increase in the area of the program memory.

The same can be said for a system using plural program memories or a system in which plural CPUs share a program memory.

The present invention is made to solve the above-described problems and has for its object to provide a memory device and a memory application device which realize readout of only predetermined bit data in the memory device, and which enable a reduction in burden on data processing without increasing the memory size in the memory application device, and without increasing the power consumption with an increase in processing speed of the processor.

### Measures to Solve the Problems

In order to solve the above-described problems, according to Claim 1 of the present invention, there is provided a memory device comprising: a memory circuit comprising n pieces of memory cell arrays, each memory cell array being constituted by arranging m pieces of memory cells in a column direction and n pieces of memory cells in a word direction (m,n: integers that satisfy m,n≧2) in an array, each memory cell being able to store data of 1 bit, and the n pieces of memory cell arrays being allocated such that data of an i-th bit among data comprising n bits is stored in an i-th memory cell array (i: integer that satisfies 0≦i≦n−1); a word decoder for simultaneously selecting m pieces of word lines from each of the n pieces of memory cell arrays; a column decoder for simultaneously selecting n pieces of column lines from each of the n pieces of memory cell arrays; and a data sequence switching and outputting unit which switchingly outputs either of data of n bits comprising every 1 bit from the respective memory cell arrays that store 0th bit to (n−1)th bit of the n-bit data, or data of n bits obtained from the same word in one of the memory cell arrays which stores one bit among the 0th bit to the (n−1)th bit, to n pieces of data output lines according to a data sequence switching signal.

Further, according to Claim 2 of the present invention, in the memory device defined in Claim 1, the data sequence switching and outputting unit includes, for each of the memory cell arrays corresponding to the bit 0 to the bit n−1, a j-th multiplexer circuit which outputs either of the i-th output or the j-th output of the column decoder (j: integer that satisfies 0≦j≦n−1 and i≠j) according to the data sequence switching signal; an i-th buffer circuit which can control as to whether the output of the i-th column line of the memory cell array corresponding to the bit i should be outputted to the i-th data output line or not, according to the i-th output of the column decoder; and a j-th buffer circuit which can control as to whether the output of the j-th column line of the memory cell array corresponding to the bit i should be outputted or not, according to the output of the j-th multiplexer, and which can select any of the i-th to j-th data output lines to which the output of the j-th column line should be outputted, according to the data sequence switching signal.

Further, according to Claim 3 of the present invention, in the memory device defined in Claim 2, the j-th multiplexer circuit selects the i-th output of the column decoder when the data sequence switching signal is active, and selects the j-th output of the column decoder when the data sequence switching signal is nonactive; and the j-th buffer circuit outputs the output of the j-th column line to the j-th data line when the data sequence switching signal is active, and to the i-th data line when the data sequence switching signal is nonactive.

Further, according to Claim 4 of the present invention, there is provided a memory application device including: a display font ROM comprising a memory device as defined in Claim 1, which stores display data comprising vertical m dots×horizontal n dots, receives a display font address and a display arrangement signal that becomes effective when a display is set in the vertical direction, which is connected to the data sequence switching signal, and outputs display font data corresponding to the display font address and the display arrangement signal; and a display control device including a display operation control circuit which controls a display operation on a screen and generates the display font address on the basis of a horizontal sync signal and a vertical sync signal that are supplied from the outside, a data sequence conversion circuit which receives the display font data, and outputs, as converted font data, the display font data when the display arrangement signal is ineffective, while outputs data obtained by inverting the arrangement order of the data sequence of the display font data from the most significant bit to the least significant bit when the display arrangement signal is effective, and a display data shift register which receives the converted font data as display data through the display operation control circuit, and shift-outputs the display data.

Further, according to Claim 5 of the present invention, the memory application device defined in Claim 4 further includes a memory access control circuit which receives a display arrangement direction signal that becomes effective when a display is rotated leftward at 90° to be arranged in the vertical direction, which signal is generated by the display operation control circuit, a horizontal scanning count value that is reset when horizontal scanning for the 1st line of the font data is started, and stopped in counting when horizontal scanning for the n-th line is completed, and the display font address and the display arrangement signal, and outputs the display font address when either of the display arrangement signal or the display arrangement direction signal is ineffective, while adds n−1 to the display font address and subtracts a value obtained by doubling the horizontal scanning count value from the result of addition, and outputs the resultant value as a converted font address when both of the display arrangement signal and the display arrangement direction signal are effective; wherein the display font ROM outputs, with the display arrangement signal being connected to the data sequence switching signal, the display font data corresponding to the converted font address and the display arrangement signal; and the display control unit receives the display font data, and outputs, as converted font data, the display font data when the display arrangement signal is ineffective or the display arrangement direction signal is effective, while outputs data obtained by inverting the arrangement order of the data sequence of the display font data from the most significant bit to the least significant bit when the display arrangement signal is effective and the display arrangement direction signal is ineffective.

Further, according to Claim 6 of the present invention, there is provided a memory device comprising: a memory circuit having n×l pieces of memory cell arrays (l: integer that satisfies n≧l≧2), each memory cell array being constituted by arranging m pieces of memory cells in a column direction and n pieces of memory cells in a word direction (m,n: integers that satisfy m,n≧2) in an array, each memory cell being able to store data of 1 bit, and the n×l pieces of memory cell arrays being allocated such that data of an i-th bit among data comprising n bits is stored in an i-th memory cell array group (i: integer that satisfies 0≦i≦l−1) among memory cell array groups each comprising l pieces of memory cell arrays; a word decoder for simultaneously selecting m pieces of word lines from each of the n×l pieces of memory cell arrays; a column decoder for simultaneously selecting n pieces of column lines from each of the n×l pieces of memory cell arrays; a data sequence switching and outputting unit which switchingly outputs either of data of l bits comprising every 1 bit from the 0th to (l−1)th memory cell arrays in the i-th memory cell array group, or data of n bits comprising every l bit from the same word in one memory cell array among the 0th to (n−1)th memory cell arrays in the i-th memory cell array group, to n pieces of data output lines according to a data sequence switching signal; and a memory cell array selection unit for selecting one memory cell array from among the 0th to (n−1)th memory cell arrays in the i-th memory cell array group; wherein the data stored in the memory cell is constituted by data corresponding to l pieces of addresses in an address space.

Further, according to Claim 7 of the present invention, in the memory device defined in Claim 6, the data sequence switching and outputting unit includes, for the i pieces of memory cell arrays constituting each memory cell array group, a j-th multiplexer circuit which outputs either of the i-th output or the j-th output of the column decoder (j: integer that satisfies 0≦j≦n−1 and i≠j) according to the data sequence switching signal; an i-th buffer circuit which can control as to whether the output of the i-th column line of the memory cell array corresponding to the bit i should be outputted to the i-th data output line or not, according to the i-th output of the column decoder; and a j-th buffer circuit which can control as to whether the output of the j-th column line of the memory cell array corresponding to the bit i should be outputted or not, according to the output of the j-th multiplexer, and which can select any of the i-th to j-th data output lines to which the output of the j-th column line should be outputted, according to the data sequence switching signal.

Further, according to Claim 8 of the present invention, in the memory device defined in Claim 6, the memory cell array selection unit includes, for the l pieces of memory cell arrays constituting each memory cell array group, a logic circuit which activates either of the i-th buffer circuit or the j-th multiplexer circuit according to a memory cell array selection signal for selecting one of the 0th to (l−1)th memory cell arrays among the l pieces of memory cell arrays and n pieces of selected outputs from the column decoder.

Further, according to Claim 9 of the present invention, in the memory device defined in Claim 6, the j-th multiplexer circuit selects the i-th output of the column decoder when the data sequence switching signal is active, and selects the j-th output of the column decoder when the data sequence switching signal is nonactive; and the j-th buffer circuit outputs the output of the j-th column line to the j-th data line when the data sequence switching signal is active, and to the i-th data line when the data sequence switching signal is nonactive.

Further, according to Claim 10 of the present invention, there is provided a memory application device including: a display font ROM comprising a memory device as defined in Claim 6, which stores display data comprising vertical m dots×horizontal n dots, receives a display font address and a display arrangement signal that becomes effective when a display is set in the vertical direction, and outputs display font data according to the display font address and the display arrangement signal by using the data sequence switching signal as the display arrangement signal; and a display control device including a display operation control circuit which controls a display operation on a screen and generates the display font address on the basis of a horizontal sync signal and a vertical sync signal that are supplied from the outside, and a memory access control circuit which receives the display arrangement direction signal, the horizontal scanning count value, the display font address, and the display arrangement signal, and outputs the display font address as a converted font address when either of the display arrangement signal or the display arrangement direction signal is ineffective, while outputs a value which is obtained by adding a value of (n−1)×1 to the display font address and subtracting, from the result of addition, a result of multiplication between the horizontal scanning count value and a value of 1×2, when both of the display arrangement signal and the display arrangement direction signal are effective.

Further, according to Claim 11 of the present invention, there is provided a memory device comprising: a memory circuit having n pieces of memory cell arrays, each memory cell array being constituted by arranging m pieces of memory cells in a column direction and n pieces of memory cells in a word direction (m,n: integers that satisfy m,n≧2) in an array, each memory cell being able to rewrite data of 1 bit, and the n pieces of memory cell arrays being allocated such that data of an i-th bit among data comprising n bits is stored in an i-th memory cell array (i: integer that satisfies 0≦i≦n−1); a word decoder for simultaneously selecting m pieces of word lines from each of the n pieces of memory cell arrays; a column decoder for simultaneously selecting n pieces of column lines from each of the n pieces of memory cell arrays; a data sequence switching and outputting unit which switchingly outputs either of data of n bits comprising every 1 bit from the respective memory cell arrays that store 0th bit to (n−1)th bit of the n-bit data, or data of n bits obtained from the same word in one of the memory cell arrays which stores one bit among the 0th bit to the (n−1)th bit, to n pieces of data input/output lines according to a data sequence switching signal; a data writing unit for writing data inputted from the i-th data input/output line among the n pieces of data input/output lines into the i-th memory cell array among the n pieces of memory cell arrays, respectively; and a writing/reading control unit for operating either of the data sequence switching and outputting unit or the data writing unit according to a write enabling signal.

Further, according to Claim 12 of the present invention, in the memory device defined in Claim 11, the data sequence switching and outputting unit includes, for each memory cell array, a j-th multiplexer circuit which outputs either of the i-th output or the j-th output of the column decoder (j: integer that satisfies 0≦j≦n−1 and i≠j) according to the data sequence switching signal, an i-th buffer circuit which can control as to whether the output of the i-th column line of the memory cell array corresponding to the bit i should be outputted to the i-th data input/output line or not, according to the i-th output of the column decoder, and a j-th buffer circuit which can control as to whether the output of the j-th column line of the memory cell array corresponding to the bit i should be outputted or not, according to the output of the j-th multiplexer, and which can select any of the i-th to j-th data input/output lines to which the output of the j-th column line should be outputted, according to the data sequence switching signal; the data writing unit includes an i-th writing buffer circuit which can control as to whether the data of the i-th data input/output line should be outputted to the i-th column line of the memory cell array corresponding to the bit i; and the writing/reading control unit includes an i-th logic gate which outputs the i-th output of the column decoder to either of the data sequence switching unit or the data writing unit according to the write enabling signal, and a j-th logic gate which outputs the output of the j-th multiplexer to either of the data sequence switching unit or the data writing unit according to the write enabling signal.

Further, according to Claim 13 of the present invention, in the memory device defined in Claim 12, the j-th multiplexer circuit selects the i-th output of the column decoder when the data sequence switching signal is active, and selects the j-th output of the column decoder when the data sequence switching signal is nonactive; and the j-th buffer circuit outputs the output of the j-th column line to the j-th data line when the data sequence switching signal is active, and to the i-th data line when the data sequence switching signal is nonactive.

Further, according to Claim 14 of the present invention, there is provided a memory application device having a transmitter including: a processor; a transmission data storage RAM comprising a memory device as defined in Claim 11, in which transmission data are stored by the processor, which uses an interleave control signal that is outputted from the processor and becomes effective when the transmission data are read out, as the data sequence switching signal; and a transmission circuit to which the data read out from the transmission data storage RAM by the processor are transferred.

Further, according to Claim 15 of the present invention, there is provided a memory application device having a receiver including: a processor; a reception data storage RAM comprising a memory device as defined in Claim 11, in which reception data are stored by the processor, which uses a deinterleave control signal that is outputted from the processor and becomes effective when the reception data are read out, as the data sequence switching signal; and a reception circuit that receives the reception data that are stored in the reception data storage RAM by the processor.

Further, according to Claim 16 of the present invention, there is provided a memory application device having a transmission/reception system including: the transmitter constituting the memory application device defined in Claim 14; the receiver constituting the memory application device defined in Claim 15; and a transmission path connecting the transmitter and the receiver with each other.

Further, according to Claim 17 of the present invention, there is provided a memory application device having a processor system including: a CPU; and a program memory comprising a memory device as defined in Claim 1, which stores programs to be executed by the CPU, receives addresses outputted by the CPU, and uses a higher order address among the addresses as the data sequence switching signal.

Further, according to Claim 18 of the present invention, there is provided a memory application device having a processor system including: a program memory comprising a memory device as defined in Claim 1; a first CPU to which a first system clock signal input; a second CPU to which a second system clock signal that is obtained by inverting the first system clock signal is input; and a selection unit which selects an address signal outputted by the first CPU and an address signal outputted by the second CPU, and outputs the selected signal to the program memory; wherein the address signal outputted by the first CPU is input to the program memory when the first system clock signal is a first logic value, while the address signal outputted by the second CPU is input to the program memory when the first system clock signal is a second logic value.

### EFFECTS OF THE INVENTION

According to Claim 1 of the present invention, there is provided a memory device comprising: a memory circuit comprising n pieces of memory cell arrays, each memory cell array being constituted by arranging m pieces of memory cells in a column direction and n pieces of memory cells in a word direction (m,n: integers that satisfy m,n≧2) in an array, each memory cell being able to store data of 1 bit, and the n pieces of memory cell arrays being allocated such that data of an i-th bit among data comprising n bits is stored in an i-th memory cell array (i: integer that satisfies 0≦i≦n−1); a word decoder for simultaneously selecting m pieces of word lines from each of the n pieces of memory cell arrays; a column decoder for simultaneously selecting n pieces of column lines from each of the n pieces of memory cell arrays; and a data sequence switching and outputting unit which switchingly outputs either of data of n bits comprising every 1 bit from the respective memory cell arrays that store 0th bit to (n−1)th bit of the n-bit data, or data of n bits obtained from the same word in one of the memory cell arrays which stores one bit among the 0th bit to the (n−1)th bit, to n pieces of data output lines according to a data sequence switching signal. Therefore, it is possible to read out only predetermined data bits of information data stored in plural memory addresses, thereby reducing a memory area for storing redundant data.

Further, according to Claim 2 of the present invention, in the memory device defined in Claim 1, the data sequence switching and outputting unit includes, for each of the memory cell arrays corresponding to the bit 0 to the bit n−1, a j-th multiplexer circuit which outputs either of the i-th output or the j-th output of the column decoder (j: integer that satisfies 0≦j≦n−1 and i≠j) according to the data sequence switching signal; an i-th buffer circuit which can control as to whether the output of the i-th column line of the memory cell array corresponding to the bit i should be outputted to the i-th data output line or not, according to the i-th output of the column decoder; and a j-th buffer circuit which can control as to whether the output of the j-th column line of the memory cell array corresponding to the bit i should be outputted or not, according to the output of the j-th multiplexer, and which can select any of the i-th to j-th data output lines to which the output of the j-th column line should be outputted, according to the data sequence switching signal. Therefore, reduction in the memory area for storing redundant data can be achieved, and the data sequence switching and outputting unit can be realized with a simple construction.

Further, according to Claim 3 of the present invention, in the memory device defined in Claim 2, the j-th multiplexer circuit selects the i-th output of the column decoder when the data sequence switching signal is active, and selects the j-th output of the column decoder when the data sequence switching signal is nonactive; and the j-th buffer circuit outputs the output of the j-th column line to the j-th data line when the data sequence switching signal is active, and to the i-th data line when the data sequence switching signal is nonactive. Therefore, reduction in the memory area for storing redundant data can be achieved, and the multiplexer included in the data sequence switching and outputting unit can be realized with a simple construction.

Further, according to Claim 4 of the present invention, there is provided a memory application device including: a display font ROM comprising a memory device as defined in Claim 1, which stores display data comprising vertical m dots×horizontal n dots, receives a display font address and a display arrangement signal that becomes effective when a display is set in the vertical direction, which is connected to the data sequence switching signal, and outputs display font data corresponding to the display font address and the display arrangement signal; and a display control device including a display operation control circuit which controls a display operation on a screen and generates the display font address on the basis of a horizontal sync signal and a vertical sync signal that are supplied from the outside, a data sequence conversion circuit which receives the display font data, and outputs, as converted font data, the display font data when the display arrangement signal is ineffective, while outputs data obtained by inverting the arrangement order of the data sequence of the display font data from the most significant bit to the least significant bit when the display arrangement signal is effective, and a display data shift register which receives the converted font data as display data through the display operation control circuit, and shift-outputs the display data. Therefore, the font data for normal display can be displayed rotated at 90°, and even in an application with a TV screen being rotated rightward at 90°, the area of the display font ROM can be reduced without preparing the font data in the rotation state.

Further, according to Claim 5 of the present invention, the memory application device defined in Claim 4 further includes a memory access control circuit which receives a display arrangement direction signal that becomes effective when a display is rotated leftward at 90° to be arranged in the vertical direction, which signal is generated by the display operation control circuit, a horizontal scanning count value that is reset when horizontal scanning for the 1st line of the font data is started, and stopped in counting when horizontal scanning for the n-th line is completed, and the display font address and the display arrangement signal, and outputs the display font address when either of the display arrangement signal or the display arrangement direction signal is ineffective, while adds n−1 to the display font address and subtracts a value obtained by doubling the horizontal scanning count value from the result of addition, and outputs the resultant value as a converted font address when both of the display arrangement signal and the display arrangement direction signal are effective; wherein the display font ROM outputs, with the display arrangement signal being connected to the data sequence switching signal, the display font data corresponding to the converted font address and the display arrangement signal; and the display control unit receives the display font data, and outputs, as converted font data, the display font data when the display arrangement signal is ineffective or the display arrangement direction signal is effective, while outputs data obtained by inverting the arrangement order of the data sequence of the display font data from the most significant bit to the least significant bit when the display arrangement signal is effective and the display arrangement direction signal is ineffective. Therefore, the font data for normal display can be displayed rotated at 90° leftward or rightward, and even in an application with a TV screen being rotated at 90° leftward or rightward, the area of the display font ROM can be reduced without preparing the font data in the respective rotation states.

Further, according to Claim 6 of the present invention, there is provided a memory device comprising: a memory circuit having n×l pieces of memory cell arrays (l: integer that satisfies n≧l≧2), each memory cell array being constituted by arranging m pieces of memory cells in a column direction and n pieces of memory cells in a word direction (m,n: integers that satisfy m,n≧2) in an array, each memory cell being able to store data of 1 bit, and the n×l pieces of memory cell arrays being allocated such that data of an i-th bit among data comprising n bits is stored in an i-th memory cell array group (i: integer that satisfies 0≦i≦l−1) among memory cell array groups each comprising l pieces of memory cell arrays; a word decoder for simultaneously selecting m pieces of word lines from each of the n×l pieces of memory cell arrays; a column decoder for simultaneously selecting n pieces of column lines from each of the n×l pieces of memory cell arrays; a data sequence switching and outputting unit which switchingly outputs either of data of l bits comprising every 1 bit from the 0th to (l−1)th memory cell arrays in the i-th memory cell array group, or data of n bits comprising every 1 bit from the same word in one memory cell array among the 0th to (n−1)th memory cell arrays in the i-th memory cell array group, to n pieces of data output lines according to a data sequence switching signal; and a memory cell array selection unit for selecting one memory cell array from among the 0th to (n−1)th memory cell arrays in the i-th memory cell array group; wherein the data stored in the memory cell is constituted by data corresponding to l pieces of addresses in an address space. Therefore, even when one information data is stored over plural memory addresses and thereby it is necessary to access the logical address space not only in the row and column directions but also in the depth direction, only predetermined data bits can be read out in the depth direction for each information data, whereby the memory area for storing redundant data can be reduced by reading out only the predetermined data bits for each information data unit.

Further, according to Claim 7 of the present invention, in the memory device defined in Claim 6, the data sequence switching and outputting unit includes, for the l pieces of memory cell arrays constituting each memory cell array group, a j-th multiplexer circuit which outputs either of the i-th output or the j-th output of the column decoder (j: integer that satisfies 0≦j≦n−1 and i≠j) according to the data sequence switching signal; an i-th buffer circuit which can control as to whether the output of the i-th column line of the memory cell array corresponding to the bit i should be outputted to the i-th data output line or not, according to the i-th output of the column decoder; and a j-th buffer circuit which can control as to whether the output of the j-th column line of the memory cell array corresponding to the bit i should be outputted or not, according to the output of the j-th multiplexer, and which can select any of the i-th to j-th data output lines to which the output of the j-th column line should be outputted, according to the data sequence switching signal. Therefore, the memory area for storing redundant data can be reduced by reading out only predetermined data bits for each information data unit, and the data sequence switching and outputting unit can be realized with a simple construction.

Further, according to Claim 8 of the present invention, in the memory device defined in Claim 6, the memory cell array selection unit includes, for the l pieces of memory cell arrays constituting each memory cell array group, a logic circuit which activates either of the i-th buffer circuit or the j-th multiplexer circuit according to a memory cell array selection signal for selecting one of the 0th to (l−1)th memory cell arrays among the l pieces of memory cell arrays and n pieces of selected outputs from the column decoder. Therefore, the memory area for storing redundant data can be reduced by reading out only predetermined data bits for each information data unit, and the memory cell array selection unit can be realized by a simple construction.

Further, according to Claim 9 of the present invention, in the memory device defined in Claim 6, the j-th multiplexer circuit selects the i-th output of the column decoder when the data sequence switching signal is active, and selects the j-th output of the column decoder when the data sequence switching signal is nonactive; and the j-th buffer circuit outputs the output of the j-th column line to the j-th data line when the data sequence switching signal is active, and to the i-th data line when the data sequence switching signal is nonactive. Therefore, the memory area for storing redundant data can be reduced by reading out only predetermined data bits for each information data unit, and the multiplexer circuit and the buffer circuit included in the data sequence switching and outputting unit can be realized as those performing simple operations.

Further, according to Claim 10 of the present invention, there is provided a memory application device including: a display font ROM comprising a memory device as defined in Claim 6, which stores display data comprising vertical m dots×horizontal n dots, receives a display font address and a display arrangement signal that becomes effective when a display is set in the vertical direction, and outputs display font data according to the display font address and the display arrangement signal by using the data sequence switching signal as the display arrangement signal; and a display control device including a display operation control circuit which controls a display operation on a screen and generates the display font address on the basis of a horizontal sync signal and a vertical sync signal that are supplied from the outside, and a memory access control circuit which receives the display arrangement direction signal, the horizontal scanning count value, the display font address, and the display arrangement signal, and outputs the display font address as a converted font address when either of the display arrangement signal or the display arrangement direction signal is ineffective, while outputs a value which is obtained by adding a value of (n−1)×l to the display font address and subtracting, from the result of addition, a result of multiplication between the horizontal scanning count value and a value of l×2, when both of the display arrangement signal and the display arrangement direction signal are effective. Therefore, even when the font data having color representation of gradation colors in which 1 dot of the font data comprises plural bit data are displayed in an application with a TV screen being rotated at 90°, the area of the display font ROM can be further reduced without preparing font data in the respective rotation states.

Further, according to Claim 11 of the present invention, there is provided a memory device comprising: a memory circuit having n pieces of memory cell arrays, each memory cell array being constituted by arranging m pieces of memory cells in a column direction and n pieces of memory cells in a word direction (m,n: integers that satisfy m,n≧2) in an array, each memory cell being able to rewrite data of 1 bit, and the n pieces of memory cell arrays being allocated such that data of an i-th bit among data comprising n bits is stored in an i-th memory cell array (i: integer that satisfies 0≦i≦n−1); a word decoder for simultaneously selecting m pieces of word lines from each of the n pieces of memory cell arrays; a column decoder for simultaneously selecting n pieces of column lines from each of the n pieces of memory cell arrays; a data sequence switching and outputting unit which switchingly outputs either of data of n bits comprising every 1 bit from the respective memory cell arrays that store 0th bit to (n−1)th bit of the n-bit data, or data of n bits obtained from the same word in one of the memory cell arrays which stores one bit among the 0th bit to the (n−1)th bit, to n pieces of data input/output lines according to a data sequence switching signal; a data writing unit for writing data inputted from the i-th data input/output line among the n pieces of data input/output lines into the i-th memory cell array among the n pieces of memory cell arrays, respectively; and a writing/reading control unit for operating either of the data sequence switching and outputting unit or the data writing unit according to a write enabling signal. Therefore, it is possible to store arbitrary information data in plural memory addresses and read out only predetermined data bits, thereby reducing the memory area for storing redundant data.

Further, according to Claim 12 of the present invention, in the memory device defined in Claim 11, the data sequence switching and outputting unit includes, for each memory cell array, a j-th multiplexer circuit which outputs either of the i-th output or the j-th output of the column decoder (j: integer that satisfies 0≦j≦n−1 and i≠j) according to the data sequence switching signal, an i-th buffer circuit which can control as to whether the output of the i-th column line of the memory cell array corresponding to the bit i should be outputted to the i-th data input/output line or not, according to the i-th output of the column decoder, and a j-th buffer circuit which can control as to whether the output of the j-th column line of the memory cell array corresponding to the bit i should be outputted or not, according to the output of the j-th multiplexer, and which can select any of the i-th to j-th data input/output lines to which the output of the j-th column line should be outputted, according to the data sequence switching signal; the data writing unit includes an i-th writing buffer circuit which can control as to whether the data of the i-th data input/output line should be outputted to the i-th column line of the memory cell array corresponding to the bit i; and the writing/reading control unit includes an i-th logic gate which outputs the i-th output of the column decoder to either of the data sequence switching unit or the data writing unit according to the write enabling signal, and a j-th logic gate which outputs the output of the j-th multiplexer to either of the data sequence switching unit or the data writing unit according to the write enabling signal. Therefore, the memory area for storing redundant data can be reduced by the data sequence switching and outputting unit having the above-described construction.

Further, according to Claim 13 of the present invention, in the memory device defined in Claim 12, the j-th multiplexer circuit selects the i-th output of the column decoder when the data sequence switching signal is active, and selects the j-th output of the column decoder when the data sequence switching signal is nonactive; and the j-th buffer circuit outputs the output of the j-th column line to the j-th data line when the data sequence switching signal is active, and to the i-th data line when the data sequence switching signal is nonactive. Therefore, the memory area for storing redundant data can be reduced by that the multiplexer circuit and the buffer circuit perform the above-mentioned operations.

Further, according to Claim 14 of the present invention, there is provided a memory application device having a transmitter including: a processor; a transmission data storage RAM comprising a memory device as defined in Claim 11, in which transmission data are stored by the processor, which uses an interleave control signal that is outputted from the processor and becomes effective when the transmission data are read out, as the data sequence switching signal; and a transmission circuit to which the data read out from the transmission data storage RAM by the processor are transferred. Therefore, a special memory for interleaving and a memory area for storing interleaved data are dispensed with, resulting in a reduction in the memory area.

Further, according to Claim 15 of the present invention, there is provided a memory application device having a receiver including: a processor; a reception data storage RAM comprising a memory device as defined in Claim 11, in which reception data are stored by the processor, which uses a deinterleave control signal that is outputted from the processor and becomes effective when the reception data are read out, as the data sequence switching signal; and a reception circuit that receives the reception data that are stored in the reception data storage RAM by the processor. Therefore, a special memory for deinterleaving and a memory area for storing deinterleaved data are dispensed with, resulting in a reduction in the memory area.

Further, according to Claim 16 of the present invention, there is provided a memory application device having a transmission/reception system including: the transmitter constituting the memory application device defined in Claim 14; the receiver constituting the memory application device defined in Claim 15; and a transmission path connecting the transmitter and the receiver with each other. Therefore, special memories for interleaving and deinterleaving and memory areas for storing interleaved data and deinterleaved data are dispensed with, resulting in a reduction in the memory area as well as a reduction in the burden on the processor.

Further, according to Claim 17 of the present invention, there is provided a memory application device having a processor system including: a CPU; and a program memory comprising a memory device as defined in Claim 1, which stores programs to be executed by the CPU, receives addresses outputted by the CPU, and uses a higher order address among the addresses as the data sequence switching signal. Therefore, a plurality of different programs can be executed using the same memory area, thereby reducing the memory size of the program memory.

Further, according to Claim 18 of the present invention, there is provided a memory application device having a processor system including: a program memory comprising a memory device as defined in Claim 1; a first CPU to which a first system clock signal input; a second CPU to which a second system clock signal that is obtained by inverting the first system clock signal is input; and a selection unit which selects an address signal outputted by the first CPU and an address signal outputted by the second CPU, and outputs the selected signal to the program memory; wherein the address signal outputted by the first CPU is input to the program memory when the first system clock signal is a first logic value, while the address signal outputted by the second CPU is input to the program memory when the first system clock signal is a second logic value. Therefore, even when plural CPUs exist, a plurality of different programs can be executed using the same memory area in one program memory, thereby reducing the memory size of the program memory.

### BRIEF DESCRIPTION OF THE DRAWINGS

FIG. 1 is a block diagram illustrating a schematic construction of a memory device according to a first embodiment of the present invention.

FIG. 2(a) is a diagram illustrating a number “1” comprising 4×4 dots, for explaining the principle of address conversion operation of the memory device according to the first embodiment.

FIG. 2(b) is a diagram illustrating addresses assigned to the number “1” comprising 4×4 dots, for explaining the principle of data sequence conversion operation of the memory device according to the first embodiment.

FIG. 2(c) is a diagram illustrating data of address 0 which are read out by first horizontal scanning, for explaining the principle of the data sequence conversion operation of the memory device according to the first embodiment.

FIG. 2(d) is a diagram illustrating font data which are read out by the first horizontal scanning, for explaining the principle of the data sequence conversion operation of the memory device according to the first embodiment.

FIG. 2(e) is a diagram illustrating the state where a display is rotated at 90° in the clockwise direction, for explaining the principle of data sequence conversion operation of the memory device according to the first embodiment.

FIG. 2(f) is a diagram illustrating addresses which are read out in the state where the display is rotated at 90° in the clockwise direction, for explaining the principle of data sequence conversion operation of the memory device according to the first embodiment.

FIG. 2(g) is a diagram illustrating the state where font is displayed in its elected state, for explaining the principle of data sequence conversion operation of the memory device according to the first embodiment.

FIG. 3 is a block diagram illustrating a schematic construction of a first display control device as a memory application device according to a second embodiment of the present invention.

FIG. 4 is a diagram illustrating a data sequence conversion circuit shown in FIG. 3.

FIG. 5(a) is a diagram illustrating the state of font data shown in FIG. 3.

FIG. 5(b) is a diagram illustrating the state of the font data shown in FIG. 3 which are displayed when the TV screen is arranged horizontally long.

FIG. 5(c) is a diagram illustrating the state of the font data shown in FIG. 3 which are displayed when the TV screen is arranged vertically long.

FIG. 6 is a block diagram illustrating a schematic construction of a second display control device as a memory application device according to the second embodiment of the present invention.

FIG. 7 is a diagram illustrating a memory access control circuit shown in FIG. 6.

FIG. 8 is a diagram illustrating a data sequence conversion circuit shown in FIG. 6.

FIG. 9(a) is a diagram illustrating the state of font data shown in FIG. 6.

FIG. 9(b) is a diagram illustrating the state of the font data shown in FIG. 6 which are displayed when the TV screen is arranged horizontally long.

FIG. 9(c) is a diagram illustrating the state of the font data shown in FIG. 6 which are displayed when the TV screen is arranged vertically long.

FIG. 10 is a block diagram illustrating a schematic construction of a memory device according to a third embodiment of the present invention.

FIG. 11 is a block diagram illustrating a schematic construction of a memory access control circuit in a third display control device as a memory application apparatus according to a fourth embodiment of the present invention.

FIG. 12(a) is a diagram illustrating the state of font data according to the fourth embodiment.

FIG. 12(b) is a diagram illustrating the state of the font data according to the fourth embodiment which are displayed when the TV screen is arranged horizontally long.

FIG. 12(c) is a diagram illustrating the state of the font data according to the fourth embodiment which are displayed when the TV screen is arranged vertically long.

FIG. 13 is a block diagram illustrating a schematic construction of a memory device according to a fifth embodiment of the present invention.

FIG. 14 is a block diagram illustrating a schematic construction of a transmission/reception system as a memory application apparatus according to a sixth embodiment of the present invention.

FIG. 15(a) is a flowchart illustrating command steps in a processor on a transmitter end according to the sixth embodiment.

FIG. 15(b) is a flowchart illustrating command steps in a processor on a receiver end according to the sixth embodiment.

FIG. 16(a) is a block diagram illustrating a schematic construction of a processor system using a first CPU as a memory application apparatus according to a seventh embodiment of the present invention.

FIG. 16(b) is a block diagram illustrating a schematic construction of a processor system using first and second CPUs as a memory application apparatus according to the seventh embodiment of the present invention.

FIG. 17 is a block diagram illustrating a construction of a ROM as a conventional memory device.

FIG. 18 is a block diagram illustrating a construction of a display control device as a conventional memory application apparatus.

FIG. 19(a) is a diagram illustrating the state of font data shown in FIG. 18.

FIG. 19(b) is a diagram illustrating the state of the font data shown in FIG. 18 which are displayed when the TV screen is arranged horizontally long.

FIG. 19(c) is a diagram illustrating the state of the font data shown in FIG. 18 which are displayed when the TV screen is arranged vertically long.

FIG. 20(a) is a diagram illustrating the state where the TV screen is arranged horizontally long.

FIG. 20(b) is a diagram illustrating the state where the TV screen is arranged vertically long.

FIG. 20(c) is a diagram illustrating the state where a number “1” comprising 4×4 dots is displayed on a TV screen that is arranged horizontally long.

FIG. 20(d) is a diagram illustrating the state where a number “1” comprising 4×4 dots is displayed on a TV screen that is arranged vertically long.

FIG. 21(a) is a diagram illustrating layers in the case where the font data shown in FIG. 18 is displayed on a TV screen with its color representation being gradation colors.

FIG. 21(b) is a diagram illustrating horizontal scanning in the case where the font data shown in FIG. 18 is displayed on a TV screen with its color representation being gradation colors.

FIG. 22 is a diagram illustrating a logical address space image of font data stored in a memory, shown in FIG. 20.

FIG. 23 is a block diagram illustrating a construction of a transmission/reception system as a conventional memory application device.

FIG. 24(a) is a diagram illustrating an example of transmission data in the transmission/reception system shown in FIG. 23.

FIG. 24(b) is a diagram illustrating another example of transmission data in the transmission/reception system shown in FIG. 23.

FIG. 25(a) is a flowchart in the case where interleaving is realized by using a logical operation function of a processor in an ordinary RAM.

FIG. 25(b) is a flowchart in the case where deinterleaving is realized by using a logical operation function of a processor in an ordinary RAM.

FIG. 26 is a block diagram illustrating a construction of a processor system using a CPU as a conventional memory application device.

### DESCRIPTION OF REFERENCE NUMERALS

100 . . . memory block
1₀, 1₁, 1₂, 1₃, . . . , 1ₙ₋₁ . . . memory cell arrays
101, 201, 301 . . . data sequence switching units
102 . . . word decoder
103 . . . column decoder
2₀, . . . , 2ₘ₋₁ . . . word selection signals
3₀, . . . , 3ₙ₋₁ . . . column selection signals
0₀₀, . . . , 0ₘ₋₁ₙ₋₁, 1₀₀, . . . , 1ₘ₋₁ₙ₋₁, 2₀₀, . . . , 2ₘ₋₁ₙ₋₁, 3₀₀, . . . , 3ₘ₋₁ₙ₋₁, . . . , n−1₀₀, . . . , n−1ₘ₋₁ₙ₋₁ . . . memory cells
20₀, . . . , 20₋₁, 21₀ . . . , 21ₙ₋₁, . . . , 2n−1₀, . . . , 2n−1ₙ₋₁, 40₀, . . . , 40ₙ₋₁ . . . buffer circuits
30₀, . . . , 30ₙ₋₁, 31₀ . . . , 31₋₁, . . . , 3n−1₀, . . . , 3n−1ₙ₋₁ . . . multiplexers
4₀, . . . , 4ₙ₋₁ . . . data outputs
41₀, . . . , 41ₙ₋₁ . . . data outputs
50₀, . . . , 50ₙ₋₁, 51₀, . . . , 51ₙ₋₁, 52₀, . . . , 52ₙ₋₁, 53₀, . . . , 53ₙ₋₁, 50₀a, . . . , 50ₙ₋₁a, 50₀b, . . . , 50ₙ₋₁b, . . . 2-input AND gates
104 . . . memory cell array selection part
105 . . . data writing unit
106 . . . writing/reading control unit
131 . . . data sequence switching signal
206 . . . display font ROM
503 . . . display operation control circuit
509 . . . display data shift register
513 . . . data sequence conversion circuit
517 . . . memory access control circuit
600, 1000 . . . adders
601, 1001 . . . multipliers

### BEST MODE TO EXECUTE THE INVENTION

Hereinafter, memory devices and memory application devices according to embodiments of the present invention will be described with reference to the drawings.

### Embodiment 1

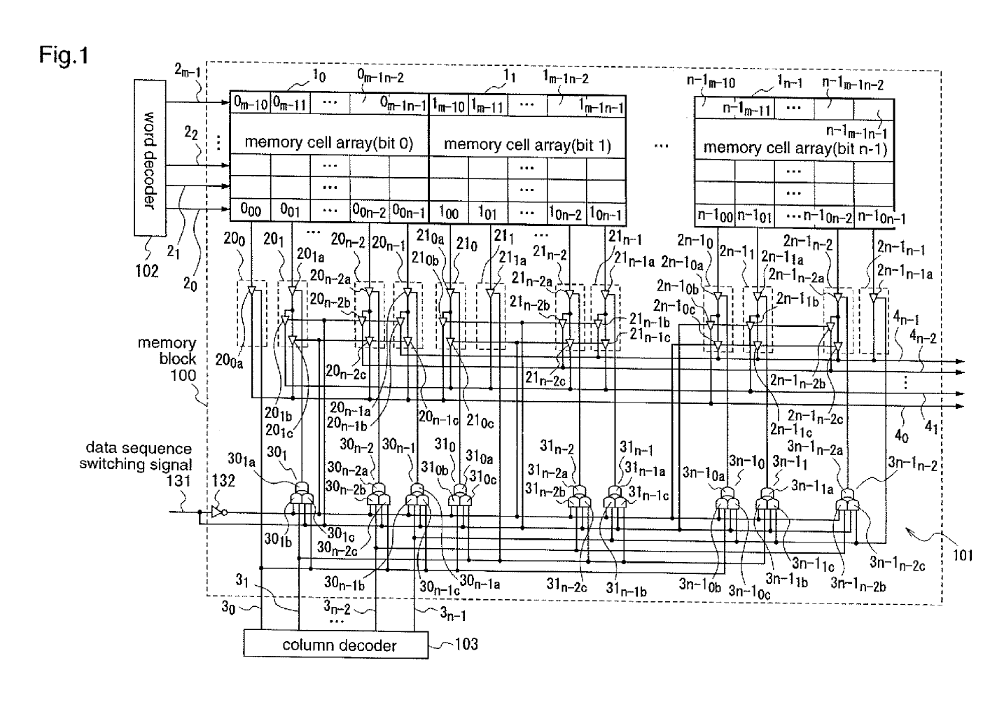

Initially, a memory device according to a first embodiment of the present invention will be described with reference to the drawings. FIG. 1 is a block diagram illustrating the schematic construction of the memory device according to the first embodiment.

In FIG. 1, 100 denotes a memory block, 1₀, 1₁, . . . , 1ₙ₋₁ denote memory cell arrays, 2₀, 2₁, . . . , 2ₘ₋₁ denote word selection signals, 3₀, 3₁, . . . , 3ₙ₋₁ denote column selection signals, 0₀₀, 0₀₁, . . . , 0ₘ₋₁ₙ₋₁, 1₀₀, 1₀₁, . . . , 1ₘ₋₁ₙ₋₁, . . . , n−1₀₀, n−1₀₁, . . . , n−1ₘ₋₁ₙ₋₁ denote memory cells, and 4₀, 4₁, . . . , 4ₙ₋₁ denote data outputs.

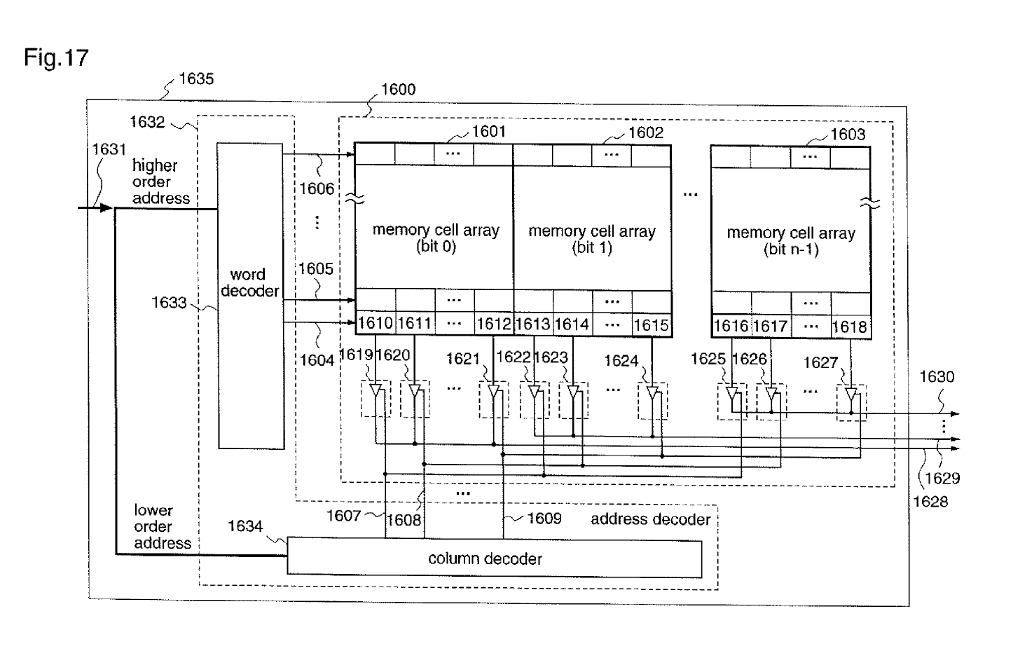

These are identical to the memory cell arrays 1601, 1602, . . . , 1603, the word selection signals 1604, 1605, . . . , 1606, the column selection signals, 1607, 1608, . . . , 1609, the memory cells 1610, 1611, . . . , 1612, 1613, 1614, . . . , 1615, 1616, 1617, . . . , 1618, and the data outputs 1628, 1629, . . . , 1630 of the conventional memory device 1635 shown in FIG. 17, respectively.

The memory cells 0₀₀, 0₀₁, . . . , 0ₘ₋₁ₙ₋₁, 1₀₀, 1₀₁, . . . , 1ₘ₋₁ₙ₋₁, . . . , n−1₀₀, n−1₀₁, . . . , n−1ₘ₋₁ₙ₋₁ are mutually connected in the horizontal direction by m pieces of word lines which are not shown, and are mutually connected in the vertical direction by n pieces of column lines (for each memory cell array) which are not shown.

The word selection signals are input to the m pieces of word lines.

2iᵢ (i=0 to n−1) denotes a buffer circuit having a sense amplifying function for amplifying the outputs of the memory cell iᵢᵢ and other memory cells that are connected to the same column line (not shown) as the memory cell iᵢᵢ, and a gate function for controlling output/non-output of the amplification result by the column selection signal 3ᵢ.

2iⱼ (i,j=0 to n−1, i≠j) denotes a buffer circuit having a sense amplifying function for amplifying the outputs of the memory cell iᵢⱼ and other memory cells that are connected to the same column line (not shown) as the memory cell iᵢⱼ, and a gate function for controlling output/non-output of the amplification result by an output of a multiplexer 3iⱼ, a data sequence switching signal 131, and an inversion signal of the data sequence switching signal 131 (obtained by an inverter 132).

The buffer circuits corresponding to the column addresses i of the memory cell arrays 1ᵢ of bit i (i=0, 1, . . . , n−1), i.e., the buffer circuit 20₀ corresponding to the memory cell 0₀₀ in the memory cell array 1₀ of bit 0, the buffer circuit 21₁ corresponding to the memory cell 1₀₁ in the memory cell array 1₁ of bit 1, . . . , the buffer circuit 2n−1ₙ₋₁ corresponding to the memory cell n−1₀ₙ₋₁ in the memory cell array 1ₙ₋₁ of bit n−1, are composed of individual buffer circuits 20₀a, 21₁a, . . . , 2n−1ₙ₋₁a, respectively.

On the other hand, each of other buffer circuits 20₁, . . . , 20ₙ₋₁, 21₀, 21₂ (not shown), . . . , 21ₙ₋₁, . . . , 2n−1₀, 2n−1₁, . . . , 2n−1ₙ₋₂ comprises three buffer circuits, that is,

buffer circuits 20₁a, . . . , 20ₙ₋₁a, 21₀a, 21₂a (not shown), . . . , 21ₙ₋₁a, . . . , 2n−1₀a, 2n−1₁a, . . . , 2n−1ₙ₋₂a, and

buffer circuits 20₁b, . . . , 20ₙ₋₁b, 21₀b, 21₂b (not shown), . . . , 21ₙ₋₁b, . . . , 2n−1₀b, 2n−1₁b, . . . , 2n−1ₙ₋₂b, and

buffer circuits 20₁c, . . . , 20ₙ₋₁c, 21₀c, 21₂c (not shown), . . . , 21ₙ₋₁c, . . . , 2n−1₀c, 2n−1₁c, . . . , 2n−1ₙ₋₂c.

The reason is as follows. There exists a so-called fixed point that requires no conversion even when rotation of font data is performed, and a buffer circuit corresponding to this fixed point can be constituted by one buffer circuit. The individual buffer circuits 2iᵢa are respectively controlled by only the column selection signals 3ᵢ, and the outputs thereof are respectively connected to the data outputs 4ᵢ.

The buffer circuits 20₀a, . . . , 20ₙ₋₁a, 21₀a, . . . , 21ₙ₋₁a, . . . , 2n−1₀a, . . . , 2n−1ₙ₋₁a which are constituents of the buffer circuits 20₀, . . . , 20ₙ₋₁, 21₀, . . . , 21ₙ₋₁, . . . , 2n−1₀, . . . , 2n−1ₙ₋₁, are connected to the column lines (not shown) corresponding to the memory cells 0₀₀, . . . , 0₀ₙ₋₁, 1₀₀, . . . , 1₀ₙ₋₁, . . . , n−1₀₀, . . . , n−1₀ₙ₋₁, respectively.

The outputs of the buffer circuits 20₀a, 21₂a, . . . , 2n−1ₙ₋₁a are connected to the data outputs 4₀, 4₁, . . . , 4ₙ₋₁, respectively.

Further, the buffer circuits 20₁b, . . . , 20ₙ₋₁b, 21₀b, 21₂b (not shown), . . . , 21ₙ₋₁b, . . . , 2n−1₀b, . . . , 2n−1ₙ₋₂b are connected to the stages subsequent to the buffer circuits 20₁a, . . . , 20ₙ₋₁a, 21₀a, 21₂a (not shown), . . . , 21ₙ₋₁a, . . . , 2n−1₀a, . . . , 2n−1ₙ₋₂a, respectively, and the outputs thereof are connected to the data outputs 4₁, . . . , 4ₙ₋₁, 4₀, 4₂ (not shown), . . . , 4ₙ₋₁, . . . , 4₀, . . . , 4ₙ₋₂, respectively.

Further, the buffer circuits 20₁c, . . . , 20ₙ₋₁c, 21₀c, 21₂c (not shown), . . . , 21ₙ₋₁c, . . . , 2n−1₀c, . . . , 2n−1ₙ₋₂c are connected to the stages subsequent to the buffer circuits 20₁a, . . . , 20ₙ₋₁a, 21₀a, 21₂a (not shown), . . . , 21ₙ₋₁a, . . . , 2n−1₀a, . . . , 2n−1ₙ₋₂a, respectively, and the outputs thereof are connected to the data outputs 4₀, . . . , 4₀, 4₁, 4₁, . . . , 4₁, . . . , 4ₙ₋₁, . . . , 4ₙ₋₁, respectively.

The multiplexer 30₁ is selectively controlled by the data sequence switching signal 131, and outputs a column selection signal 3₁ when the data sequence switching signal 131 is L level and outputs a column selection signal 3₀ when it is H level. Likewise, the multiplexer 30ₙ₋₁ outputs a column selection signal 3ₙ₋₁ when the data sequence switching signal 131 is L level, and outputs a column selection signal 3₀ when it is H level.

The multiplexer 31₀ outputs a column selection signal 3₀ when the data sequence switching signal 131 is L level, and outputs a column selection signal 3₁ when it is H level. The multiplexer 30₂ (not shown) outputs a column selection signal 3₂ (not shown) when the data sequence switching signal 131 is L level, and outputs a column selection signal 3₁ when it is H level.

The multiplexer 31ₙ₋₁ outputs a column selection signal 3ₙ₋₁ when the data sequence switching signal 131 is L level, and outputs a column selection signal 3₁ when it is H level. The multiplexer 3n−1₀ outputs a column selection signal 3₀ when the data sequence switching signal 131 is L level, and outputs a column selection signal 3ₙ₋₁ when it is H level.

The multiplexer 3n−1ₙ₋₂ outputs a column selection signal 3ₙ₋₂ when the data sequence switching signal 131 is L level, and outputs a column selection signal 3ₙ₋₁ when it is H level.

Further, the multiplexers 30₁, . . . , 30ₙ₋₁, 31₀, 31₂ (not shown), . . . , 31ₙ₋, . . . , 3n−1₀, . . . , 3n−1ₙ₋₂ have 2-input OR gates 30₁a, . . . , 30ₙ₋₁a, 31₀a, 31₂a (not shown), . . . , 31ₙ₋₁a, . . . , 3n−1₀a, . . . , 3n−1ₙ₋₂a, and 2-input AND gates 30₁b, . . . , 30ₙ₋₁b, 31₀b, 31₂b (not shown), . . . , 31ₙ₋₁b, . . . , 3n−1₀b, . . . , 3n−1ₙ₋₁b, and 2-input AND gates 30₁c, . . . , 30ₙ₋₁c, 31₀c, 31₂c (not shown), . . . , 31ₙ₋₁c, . . . , 3n−1₀c, . . . , 3n−1ₙ₋₂c, respectively.

The outputs of the 2-input AND gates kb (k=30₁, . . . , 30ₙ₋₁, 31₀, 31₂ (not shown), . . . , 31ₙ₋₁, . . . , 3n−1₀, . . . , 3n−1ₙ₋₂) and the 2-input AND gates kc are received by two-input OR gates ka. The outputs of the multiplexers k are as follows.

It is assumed that the codes in the right terms in the following formulae indicate the logical values of the corresponding signal lines, “/” indicates inversion of the logical values of the signals, and “·” indicates the logical products.

output of multiplexer 30₁=/131·3₁+131·3₀

•

•

output of multiplexer 30ᵢ=/131·3ᵢ+131·3₀ (not shown)

•

•

output of multiplexer 30ₙ₋₁=/131·3ₙ₋₁+131·3₀

output of multiplexer 31₀=/131·3₀+131·3₁

output of multiplexer 31₂=/131·3₂+131·3₁ (not shown)

•

•

output of multiplexer 3₁₁=/131·3ᵢ+131·3₁ (not shown)

•

•

output of multiplexer 31ₙ₋₁=/131·3ₙ₋₁+131·3₁

•

•

•

output of multiplexer 3n−1₀=/131·3₀+131·3ₙ₋₁

•

•

output of multiplexer 3n−1ᵢ=/131·3ᵢ+131·3ₙ₋₁ (not shown)

•

•

output of multiplexer 3n−1ₙ₋₂=/131·3ₙ₋₂+131·3ₙ₋₁

Further, the control signals for the buffer circuits 20₁a, . . . , 20ₙ₋₁a, 21₀a, 21₂a (not shown), . . . , 21ₙ₋₁a, . . . , 2n−1₀a, . . . , 2n−1ₙ₋₂a are the output signals of the multiplexers 30₁, 30ₙ₋₁, 31₀, 31₁ (not shown), . . . , 31ₙ₋₁, . . . , 3n−1₀, . . . , 3n−1ₙ₋₂.

The control signal for the buffer circuits 20₁b, . . . , 20ₙ₋₁b, 21₀b, 21₂b (not shown), . . . , 21ₙ₋₁b, . . . , 2n−1₀b, . . . , 2n−1ₙ₋₂b is the data sequence switching signal 131 itself, and the control signal for the buffer circuits 20₁c, . . . , 20ₙ₋₁c, 21₀c, 21₂c (not shown), . . . , 21ₙ₋₁c, . . . , 2n−1₀c, . . . , 2n−1ₙ₋₂c is an inversion signal of the data sequence switching signal 131 which is obtained by the inverter 132.

Further, a data sequence switching and outputting unit 101 comprises the above-described buffer circuits 20₀, . . . , 2iᵢ, . . . , 2n₋₁ₙ₋₁, buffer circuits 20₁, . . . , 20ₙ₋₁, 21₀, 21₂ (not shown), . . . , 21ₙ₋₁, . . . , 2n−1₀, . . . , 2n−1ₙ₋₂, and multiplexers 30₁, . . . , 30ₙ₋₁, 31₀, 31₂ (not shown), . . . , 31ₙ₋₁, . . . , 3n−1₀, . . . , 3n−1ₙ₋₂.

This data sequence switching and outputting unit 101 outputs either of data of n bits comprising every 1 bit from the respective memory cell arrays corresponding to bit 0 to bit n−1 or data of n bits from the same word of one memory cell array among the memory cell arrays corresponding to bit 0 to bit n−1, to the data outputs 4₀, . . . , 4ₙ₋₁ according to the data sequence switching signal 131.

Next, the operation will be described.

When H level is input to the word selection signal 2₀ and the column selection signal 3₀ of the memory block 100 and L level is input to the other word selection signals 2₁, . . . , 2ₘ₋₁ and column selection signals 3₁, . . . , 3ₙ₋₁, if the data sequence switching signal 131 at this time is L level, the buffer circuits 20₀, 21₀, . . . , 2n−1₀ output the outputs of the memory cells 0₀₀, 1₀₀, . . . , n−1₀₀ to the data outputs 4₀, 4₁, . . . , 4ₙ₋₁, and the other buffer circuits 20₁, . . . , 20ₙ₋₁, 21₁, . . . , 21ₙ₋₁, . . . , 2n−1₁, . . . , 2n−1ₙ₋₁ generate no outputs.

At this time, this memory device can read out the information data stored in the predetermined memory addresses, like conventional memory device.

Further, if the data sequence switching signal 131 is H level, the buffer circuits 20₀, 21₁, . . . , 2ₙ₋₁ output the outputs of the memory cells 0₀₀, 0₀₁, . . . , 0₀ₙ₋₁ to the data outputs 4₀, 4₁, . . . , 4ₙ₋₁, while the buffer circuits 21₀, 21₂ (not shown), . . . , 21ₙ₋₁, . . . , 2n−1₀, . . . , 2n−1ₙ₋₁ generate no outputs, whereby this memory device can read out only the predetermined data bits of the information data stored in the plural memory addresses.

Hereinafter, the above-mentioned two cases will be described in more detail. Initially, when the data sequence switching signal 131 is L level,

output of multiplexer 30₁=3₁

•

•

output of multiplexer 30ᵢ=3ᵢ (not shown)

•

•

output of multiplexer 30ₙ₋₁=3ₙ₋₁

output of multiplexer 31₀=3₀

•

•

output of multiplexer 31ᵢ=3ᵢ (not shown)

•

•

output of multiplexer 31ₙ₋₁=3ₙ₋₁

•

•

•

output of multiplexer 3n−1₀=3₀

•

•

output of multiplexer 3n−1ᵢ=3ᵢ (not shown)

•

•

output of multiplexer 3n−1ₙ₋₂=3ₙ₋₂

The outputs of the multiplexers corresponding to the signal which becomes H among the column selection signals 3₀, 3₁, . . . , 3ₙ₋₁ are active.

Further, since the control signal for the buffer circuits 20₁b, . . . , 20ₙ₋₁b, 21₀b, . . . , 21ₙ₋₁b, . . . , 2n−1₀b, 2n−1₁b, . . . , 2n−1ₙ₋₂b is the data sequence switching signal 131 itself, the outputs of these buffer circuits 20₁b, . . . , 20ₙ₋₁b, 21₀b, . . . , 21ₙ₋₁b, . . . , 2n−1₀b, 2n−1₁b, . . . , 2n−1ₙ₋₂b become nonactive.

Conversely, the outputs of the buffer circuits 20₁c, . . . , 20ₙ₋₁c, 21₀c, . . . , 21ₙ₋₁c, . . . , 2n−1₀c, 2n−1₁b, . . . , 2n−1ₙ₋₂c become active.

Accordingly, for example, when only the column selection signal 3₀ becomes H among the column selection signals 3₀, 3₁, . . . , 3ₙ₋₁, the outputs of the multiplexers 31₀, . . . , 3n−1₀ become active, and thereby the outputs of the buffer circuits 21₀a, . . . , 2n−1₀a are selected.

At this time, since the outputs of the buffer circuits 21₀b, . . . , 2n−1₀b are nonactive and the output of the buffer circuit 20₀a is active, the outputs of the memory cells 0₀₀, 1₀₀, . . . , n−1₀₀ appear in the data outputs 4₀, 4₁, . . . , 4ₙ₋₁.

Further, when only the column selection signal 3₁ becomes H among the column selection signals 3₀, 3₁, . . . , 3ₙ₋₁, only the outputs of the multiplexers 30₁, 32₁ (not shown), . . . , 3n−1₁ become active, and the outputs of the buffer circuits 20₁a, 22₁a (not shown), . . . , 2n−1₁a become active. Further, since the output of the buffer circuit 21₁a also becomes active, the outputs of the memory cells 0₀₁, 1₀₁, . . . , n−1₀₁ appear in the data outputs 4₀, 4₁, . . . , 4ₙ₋₁.

Hereinafter, similarly, when only a certain signal among the column selection signals 3₀, 3₁, . . . , 3ₙ₋₁ becomes H, the outputs of the respective memory cells corresponding to this signal appear in the data signals 4₀, 4₁, . . . , 4ₙ₋₁.

On the other hand, when the data sequence switching signal 131 is H level,

output of multiplexer 30₁=3₀

•

•

output of multiplexer 30ᵢ=3₀ (not shown)

•

•

output of multiplexer 30ₙ₋₁=3₀

output of multiplexer 31₀=3₁

•

•

output of multiplexer 31ᵢ=3₁ (not shown)

•

•

output of multiplexer 31ₙ₋₁=3₁

•

•

•

output of multiplexer 3n−1₀=3ₙ₋₁

•

•

output of multiplexer 3n−1ᵢ=3ₙ₋₁ (not shown)

•

•

output of multiplexer 3n−1ₙ₋₂=3ₙ₋₁

Therefore, for example, when only the signal 30 among the column selection signals 3₀, 3₁, . . . , 3ₙ₋₁ becomes H, the outputs of buffer circuits 20₀a, 20₁a, . . . , 20ₙ₋₁a become active.

At this time, since the outputs of the buffer circuits 21₁b, . . . , 20ₙ₋₁b are active and the outputs of the buffer circuits 20₁c, . . . , 20ₙ₋₁c are nonactive, the outputs of the memory cells 0₀₀, 0₀₁, . . . , 0₀ₙ₋₁ appear in the data outputs 4₀, 4₁, . . . , 4ₙ₋₁.

Further, when only the signal 3₁ among the column selection signals 3₀, 3₁, . . . , 3ₙ₋₁ becomes H, the outputs of the buffer circuits 21₀a, 21₁a, . . . , 21ₙ₋₁a become active.

At this time, since the outputs of the buffer circuits 21₀b, 21₂b (not shown), . . . , 21n₋₁b are active and the outputs of the buffer circuits 21₀c, 21₂c (not shown), . . . , 21ₙ₋₁c are nonactive, the outputs of the memory cells 1₀₀, 1₀₁, . . . , 1₀ₙ₋₁ on appear in the data outputs 4₀, 4₁, . . . , 4ₙ₋₁.

Hereinafter, similarly, when only a certain signal among the column selection signals 3₀, 3₁, . . . , 3ₙ₋₁ becomes H, all the outputs of the addresses in the same row of the memory cell array corresponding to this H signal appear in the data signals 4₀, 4₁, . . . , 4ₙ₋₁.

Hereinafter, for simplification, 4×4 font data will be described as in the conventional example.

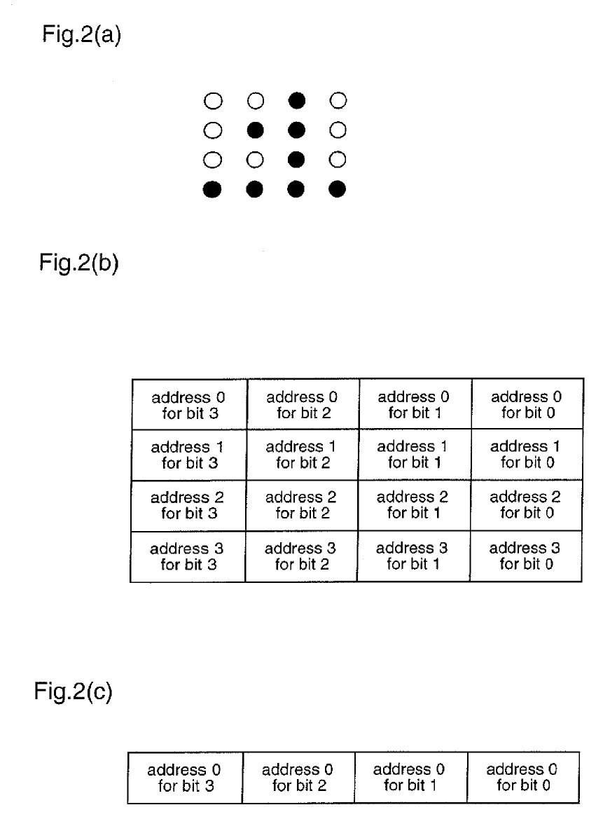

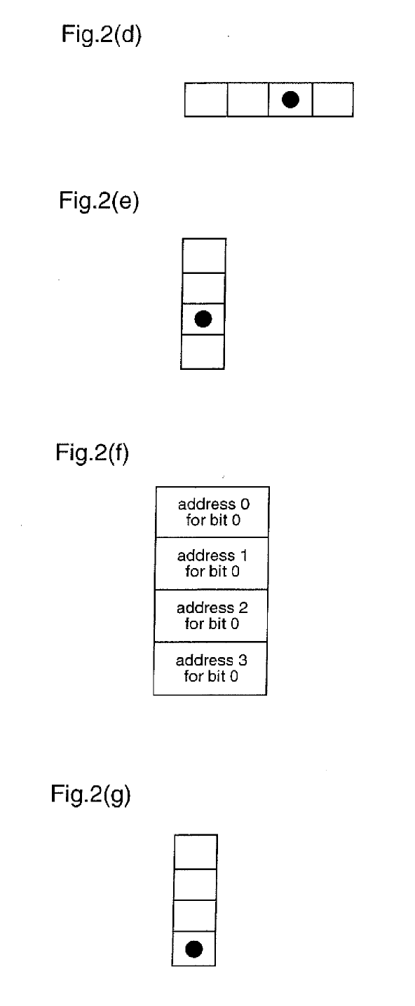

It is assumed that addresses are assigned as shown in FIG. 2(b) to the 4×4 font data “1” shown in FIG. 2(a).

When the screen is set in the normal state, i.e., in the horizontally long state, and the data sequence switching signal 131 is L level, the data of address 0 to be read out by first horizontal scanning shown in FIG. 2(c) is as shown in FIG. 2(d), and the font data in the row corresponding to the uppermost stage are read out as shown in FIG. 2(d).

By the way, when the screen is rotated at 90° in the clockwise direction, the state of FIG. 2(e) is vertically displayed at the right end on the screen. However, by setting the data sequence switching signal 131 at H, FIG. 2(f) is read out and FIG. 2(g) is displayed, whereby the font that is rotated at 90° in the anticlockwise direction is displayed. Since the screen has already been rotated at 90° in the clockwise direction, this rotation in the clockwise direction is negated, and the font is displayed in its elected state.

As described above, according to the first embodiment, the memory device is constituted such that it can control as to whether memory cells of the same address in the respective memory cell arrays should be read out or memory cells of all addresses constituting the same row in one memory cell array should be read out, according to the value of the data sequence switching signal. Therefore, it is possible to perform the two different readout operations, i.e., reading memory cells of the same address in the respective memory cell arrays from the same memory device or reading memory cells of all addresses constituting the same row in one memory cell, and it is not unnecessary to prepare separate memory devices corresponding to these two readout manners, resulting in reductions in the memory capacity and memory area.

### Embodiment 2

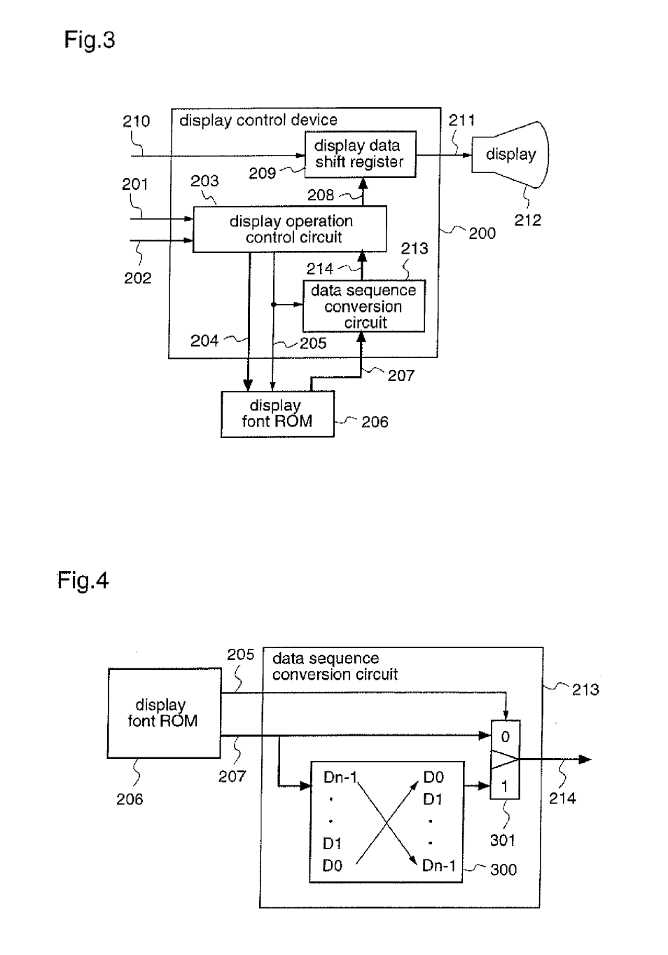

Next, a memory application device according to a second embodiment of the present invention will be described with reference to FIG. 3.

FIG. 3 is a block diagram illustrating a schematic construction of a display control device as a memory application device according to the second embodiment of the present invention.

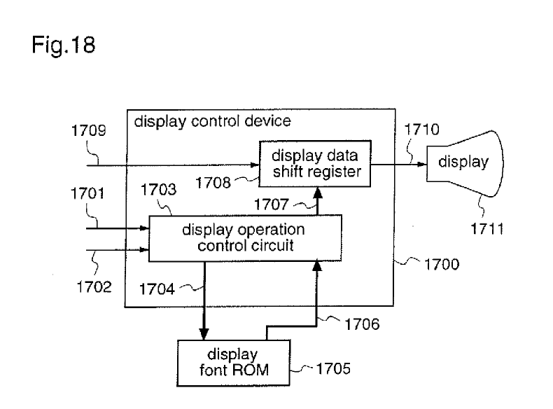

In FIG. 3, a display control device 200, a horizontal sync signal 201, a vertical sync signal 202, a display operation control circuit 203, a display font address 204, display font data 207, display data 208, a display data shift register 209, a display dot clock 210, a display signal 211, and a display 212 are identical to the display control device 1700, the horizontal sync signal 1701, the vertical sync signal 1702, the display operation control circuit 1703, the display font address 1704, the display font data 1706, the display data 1707, the display data shift register 1708, the display dot clock 1709, the display signal 1710, and the display 1711 of the conventional memory application device shown in FIG. 18, respectively.

Reference numeral 205 denotes a display arrangement signal which becomes L level when the display 212 is normally (horizontally long) arranged, and becomes H level when the display 212 is rotated at 90° to be arranged in the vertical direction (vertically long).

Reference numeral 213 denotes a data sequence conversion circuit which receives the display font data 207 and the display arrangement signal 205, outputs the display font data 207 as it is as conversion font data 214 when the display arrangement signal 205 is L level, while inverts the data sequence of the display font data 207 from the most significant bit to the least significant bit and outputs the inverted data as converted font data 214 when the display arrangement signal 205 is H level.

Reference numeral 206 denotes a display font ROM which is constituted similarly to the memory device according to the first embodiment, and the display arrangement signal 205 is connected to the data sequence switching signal 131 shown in FIG. 1.

FIG. 4 is a diagram illustrating the data sequence conversion circuit 213 shown in FIG. 3. The arrangement order of the data sequence of the display font data 207 inputted to the data sequence conversion circuit 213 is inverted from the most significant bit to the least significant bit by the sequence conversion circuit 300, and the inverted data are outputted. That is, replacement between the higher order data and the lower order data is carried out, which is required when the screen is rotated rightward at 90°.

A selector 301 is a circuit which outputs, as converted font data 214, the display font data 207 when the display arrangement signal 205 is L level, and outputs the output from the sequence conversion circuit 300 when the signal 205 is H level.

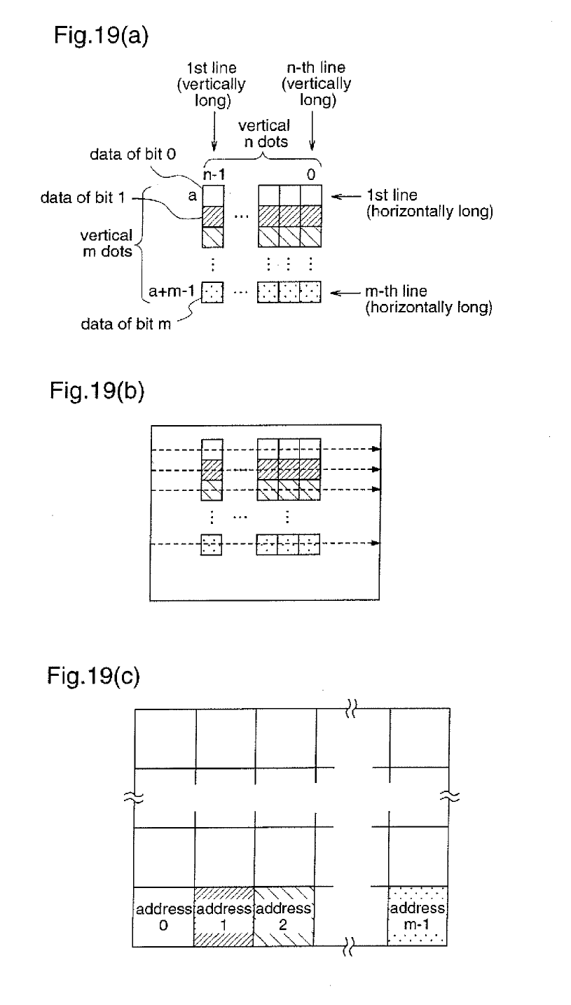

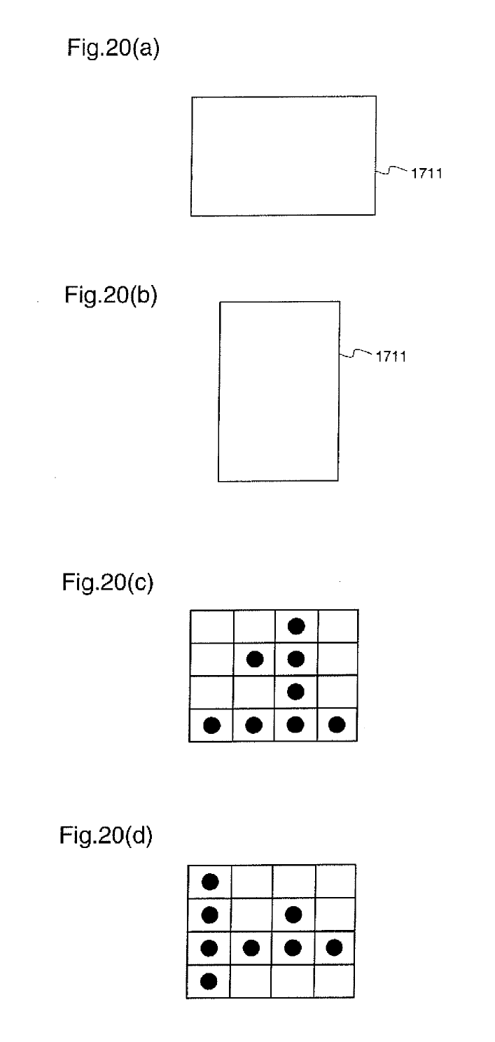

In the display control device 200 constituted as described above, when performing a display operation, since the display arrangement signal 205 is L level when the display 212 is normally arranged, the display font data 207 read out from the display font ROM 206 are identical to the font data of the conventional example shown in FIG. 19(a), and the display font data 207 are outputted as the converted font data 214 from the data sequence conversion circuit 213, and therefore, the display shown in FIG. 19(b) that is identical to the conventional display is performed on the TV screen.

On the other hand, when the display 212 is arranged in the vertical direction, since the display arrangement signal 205 becomes H level, the display font data 207 to be read out from the display font ROM 206 are read out in such a manner that the data of bit 0 in the first line of the font data shown in FIG. 19(a) is read out as the least significant bit, the data of bit 0 in the second line is read out as bit 1, . . . , and the data of bit 0 in the m-th line when the font data are vertical m dots is read out as the most significant bit, respectively.

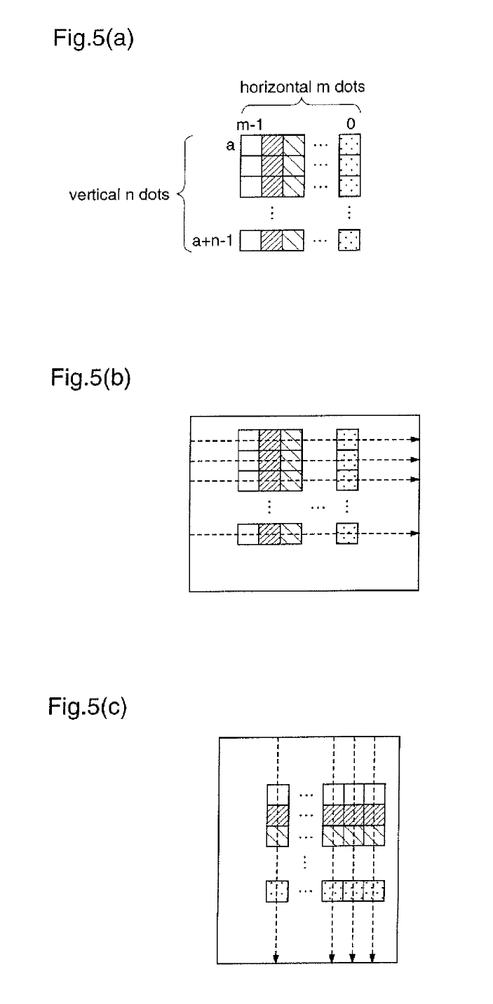

Next, the arrangement order of the data sequence is inverted from the most significant bit to the least significant bit by the data sequence conversion circuit 213, whereby the font data shown in FIG. 5(a) are displayed on the TV screen as the converted font data 214. FIG. 5(b) shows the state where the TV screen at this time is viewed from the direction where it is arranged normally (horizontally long). When the TV screen of FIG. 5(b) is rotated rightward at 90°, the state shown in FIG. 5(c) is obtained. This indicates that the font data shown in FIG. 19(a) can be displayed in its elected state even when the screen is rotated rightward at 90°.

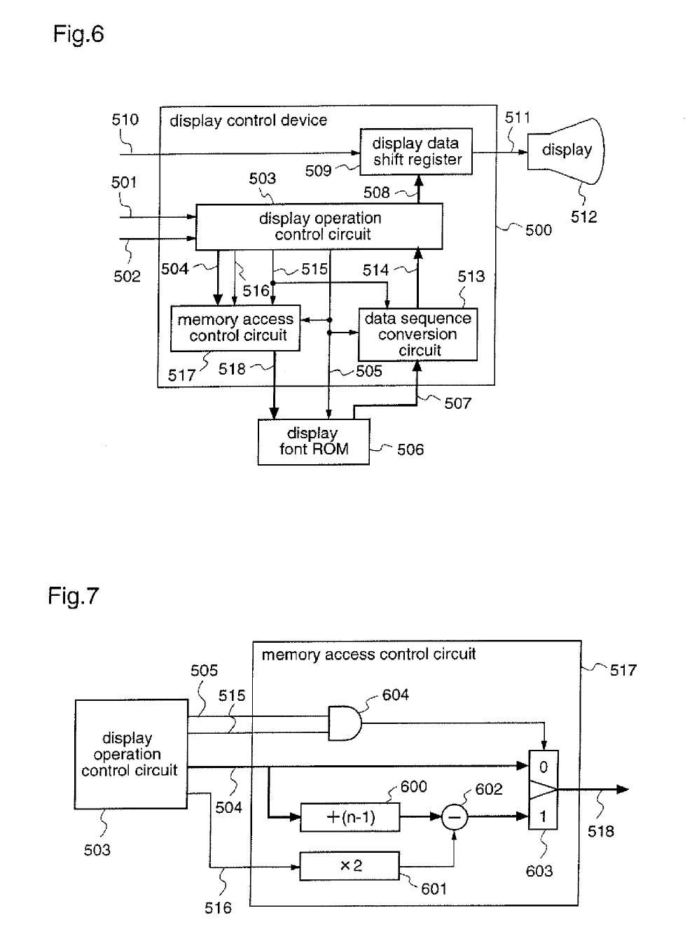

Next, FIG. 6 is a block diagram illustrating a schematic construction of another display control device as a memory application device according to the second embodiment of the present invention.

In FIG. 6, a display control device 500, a horizontal sync signal 501, a vertical sync signal 502, a display operation control circuit 503, a display font address 504, a display arrangement signal 505, a display font ROM 506, display font data 507, display data 508, a display data shift register 509, a display dot clock 510, a display signal 511, a display 512, and converted font data 514 are identical to the display control device 200, the horizontal sync signal 201, the vertical sync signal 202, the display operation control circuit 203, the display font address 204, the display arrangement signal 205, the display font ROM 206, the display font data 207, the display data 208, the display data shift register 209, the display dot clock 210, the display signal 211, the display 212, and the converted font data 214 of the memory application device shown in FIG. 3, respectively.

Reference numeral 515 denotes a display arrangement direction signal indicating the rotation direction, which becomes L level when the TV screen is normally arranged and when it is rotated rightward at 90°, and becomes H level only when the TV screen is rotated leftward at 90°.

Reference numeral 516 denotes a horizontal scanning count value which is a resultant value obtained when the horizontal sync signal 501 is counted, and it is reset to 0 when horizontal scanning for the first line of the font data is started, and stopped in counting when horizontal scanning for the n-th line when the font data includes vertical n dots is completed. Reference numeral 517 denotes a memory access control circuit for reading out the font data shown in FIG. 5(a) such that the font data to be read out for the n-th line are read out for the first line, and the font data to be read out for the first line are read out for the n-th line.

Reference numeral 518 denotes a conversion font address outputted from the memory access control circuit 517, and reference numeral 513 denotes a data sequence conversion circuit which outputs the display font data 507 as it is as the converted font data 514 when the display arrangement signal 505 is L level or when the display arrangement signal 505 is H level and the display arrangement direction signal 515 is H level, while inverts the data sequence of the display font data 507 from the most significant bit to the least significant bit and outputs the inverted data as the converted font data 514 only when the display arrangement signal 505 is H level and the display arrangement direction signal 515 is L level.

FIG. 7 is a diagram illustrating the memory access control circuit 517 shown in FIG. 6.

A value of n−1 is added by an adder 600 to the display font address 504 inputted to the memory access control circuit 517 according to the number of the vertical dots of the font data shown in FIG. 5(a), and a value obtained by doubling the horizontal scanning count value 516 with a multiplier 601 is subtracted with a subtracter 602, and the result is input to a selector 603.

Only when a 2-input AND gate 604 detects that the display arrangement signal 505 is H level and the display arrangement direction signal 515 becomes H level, the selector 603 outputs the subtraction result of the subtracter 602 as a conversion font address 518. In other cases, the selector 603 outputs the display font address 504.

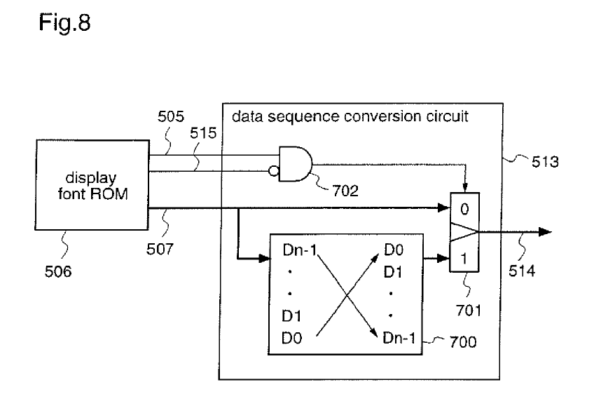

Next, FIG. 8 is a diagram illustrating the data sequence conversion circuit 513 shown in FIG. 6.

In the data sequence conversion circuit 513, a sequence conversion circuit 700 inverts the arrangement order of the data sequence of the display font data 507 from the most significant bit to the least significant bit. Only when a 2-input AND gate 702 detects that the display arrangement signal 505 is H level and the display arrangement direction signal 515 becomes L level, a selector 701 selects the output result of the sequence conversion circuit 700, and outputs it as the converted font data 514.

In other cases, the selector 701 outputs the display font data 507.

In the display control device 500 constituted as described above, when performing display operation, if the display 512 is rotated rightward at 90° to be arranged in the vertical direction, the display arrangement signal 505 becomes H level and the display arrangement direction signal 515 becomes L level, whereby the display font address 504 is outputted as it is as the converted font address 518 from the memory access control circuit 517.

Further, in the data sequence conversion circuit 513, the result obtained by that the arrangement order of the data sequence of the display font data 507 is inverted from the most significant bit to the least significant bit by the sequence conversion circuit 700 is selected by the selector 701 and outputted as the converted font data 514, whereby the same display operation as the screen display shown in FIG. 5 is carried out.

On the other hand, when the display 512 is arranged rotated leftward at 90°, since the display arrangement signal 505 becomes H level and the display arrangement direction signal 515 becomes H level, a value of n−1 is added to the display font address 504 in the memory access control circuit 517 and a value obtained by doubling the horizontal scanning count value 516 is subtracted, whereby the display font address 504 for reading out the data in the n-th line (n−1 for the horizontal scanning count value) of the font data shown in FIG. 5(a) is outputted for the first line (0 for the horizontal scanning count value) as the converted font address 518, and the display font address 504 for reading out the data in the first line is outputted for the n-th line as the converted font address 518.

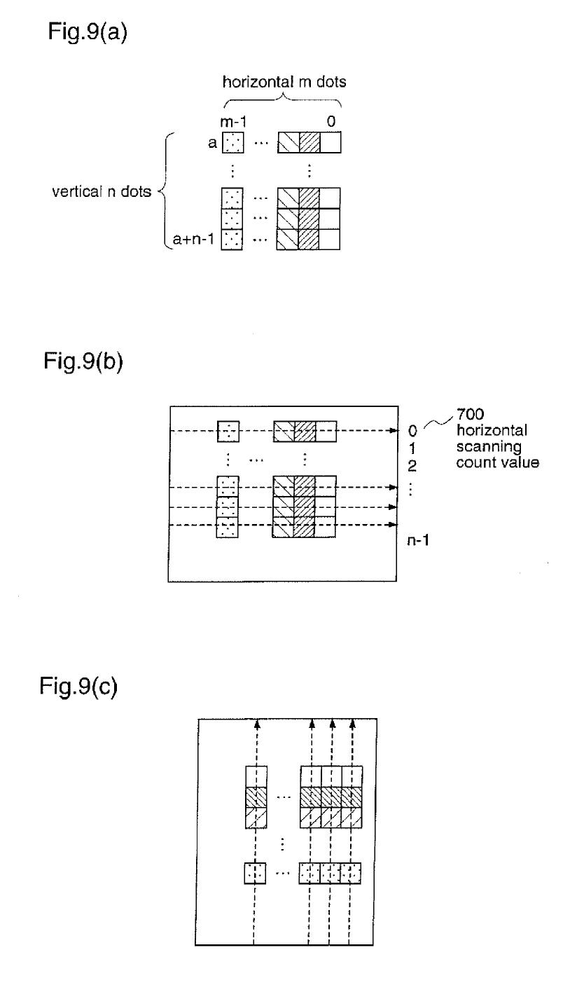

Further, in the data sequence conversion circuit 513, the display font data 507 is outputted as it is as the converted font data 514 and displayed on the TV screen, whereby the same display operation as the screen display shown in FIG. 5 is carried out. FIG. 9(a) shows the font data at this time.

The data of the most significant bit to be read out for the first line of the font data shown in FIG. 19(a) is read out and displayed as the least significant bit, the data of the most significant bit to be read out for the second line is read out and displayed as bit 1, and the data of the most significant bit to be read out for the m-th line when the font data includes vertical m dots is read out and displayed as the most significant bit.

FIG. 9(b) shows the state where the TV screen at this time is viewed from the direction where it is arranged normally. When the TV screen of FIG. 9(b) is rotated leftward at 90°, the state shown in FIG. 9(c) is obtained. This indicates that the font data shown in FIG. 19(a) can be displayed in its elected state even when the screen is rotated leftward at 90°.

As described above, according to the second embodiment, there is provided the display operation control circuit for controlling, when performing readout from the memory cells constituting the memory cell arrays, as to whether memory cells of the same address in the respective memory cell arrays should be read out or memory cells of all addresses constituting the same row in one memory cell array should be read out, according to the value of the data sequence switching signal. Therefore, it is possible to obtain a memory application device which can display the font in its elected state by using only the font data that stores the same contents in either of the state where the screen is arranged horizontally long or the state where it is rotated at 90° to be arranged vertically long.

### Embodiment 3

A memory device according to a third embodiment of the present invention will be described with reference to the drawings.

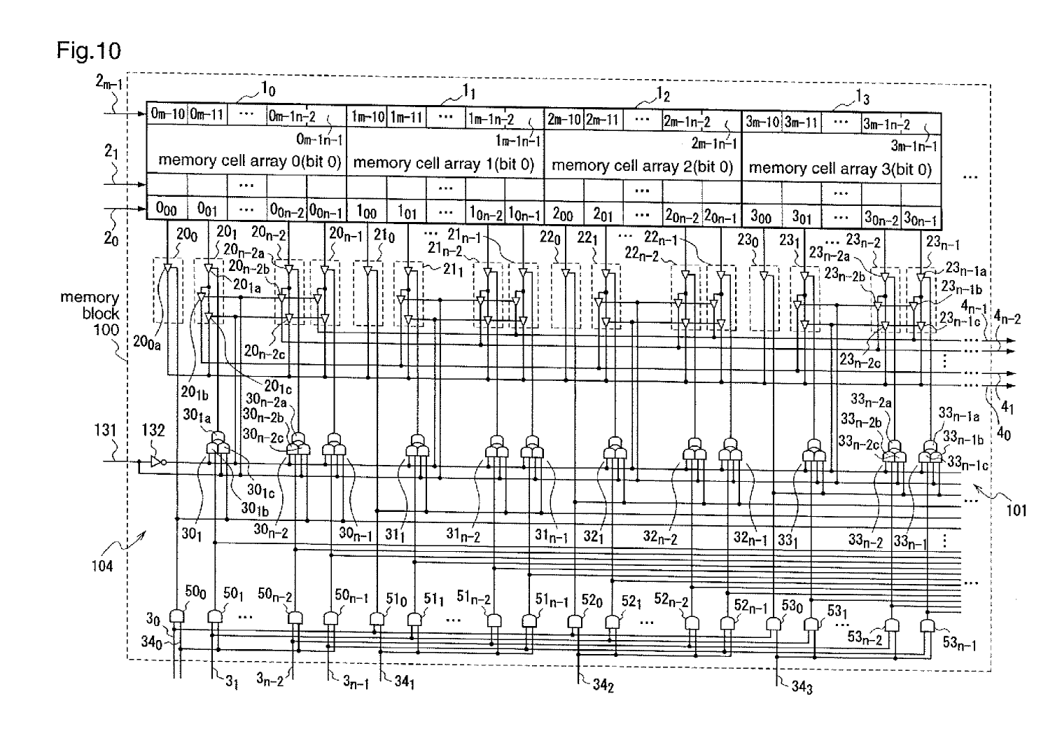

FIG. 10 is a block diagram illustrating a schematic construction of a memory device according to a third embodiment of the present invention.

In FIG. 10, the same reference numerals as those shown in FIG. 1 denote the same or corresponding elements. Reference numerals 1₀, 1₁, 1₂, and 1₃ denotes a memory cell array 0, a memory cell array, a memory cell array 2, and a memory cell array 3, respectively, and each memory cell array corresponds to bit 0 of information data.

Although it is not shown in the figure, memory cell array groups each comprising similar memory cell array 0, memory cell array 1, memory cell array 2, and memory cell array 3 are provided corresponding to bit 1 to bit n−1, respectively.

Reference numerals 2₀, . . . , 2ₘ₋₁ denote word selection signals, 0₀₀, . . . , 0ₘ₋₁ₙ₋₁, 1₀₀, . . . , 1ₘ₋₁ₙ₋₁, 2₀₀, . . . , 2ₘ₋₁ₙ₋₁, 3₀₀, . . . , 3ₘ₋₁ₙ₋₁ denote memory cells, 4₀, . . . , 4ₙ₋₁ denote data outputs, and 131 denotes a data sequence switching signal.

While only those corresponding to bit 0 of the information data are shown, those corresponding to bit 1 to bit n−1 also exist like the memory cell arrays, and they are connected by similar connection relationship as that for bit 0. Further, a word decoder and a column decoder are omitted in the figure.

Hereinafter, the construction of FIG. 10 will be described for only the bit 0.

Reference numerals 3₀, . . . , 3ₙ₋₁ denote column selection signals for selecting memory spaces that are specified by the address inputs other than the address inputs corresponding to the least significant 2 bits among the lower order addresses of the address inputs applied to the memory device.

Further, reference numerals 34₀, 34₁, 34₂, and 34₃ denote column selection signals for selecting memory spaces that are specified by the least significant 2 bits among the lower order addresses of the address inputs applied to the memory device, and the column selection signal 4₀ corresponds to the least significant memory address 0, and thereafter, similarly the column selection signal 4₁ corresponds to address 1, the column selection signal 4₂ corresponds to address 2, and the column selection signal 4₃ corresponds to address 3.

Reference numeral 20₀ denotes a buffer circuit which has a sense amplification function for amplifying the outputs of the memory cells in the same column as the memory cell 0₀₀, and controls output/non-output with the output of a 2-input AND gate 50₀.

Reference numeral 20₁ denotes a buffer circuit which has a sense amplification function for amplifying the outputs of the memory cells in the same column as the memory cell 0₀₁, and controls output/non-output with the output of the multiplexer 30₁ and the data sequence switching signal 131 as well as its inversion signal.

Reference numeral 20ₙ₋₁ denotes a buffer circuit which has a sense amplification function for amplifying the outputs of the memory cells in the same column as the memory cell 0₀ₙ₋₁, and controls output/non-output with the output of the multiplexer 30ₙ₋₁ and the data sequence switching signal 131 as well as its inversion signal.

While the construction for performing readout control for the memory cell array 10 is described above, similar constructions are provided for the other memory cell arrays 1₁ to 1₃.

That is, reference numeral 21₀ denotes a buffer circuit which has a sense amplification function for amplifying the outputs of the memory cells in the same column as the memory cell 1₀₀, and controls output/non-output with the output of a 2-input AND gate 51₀.

Reference numeral 21₁ denotes a buffer circuit which has a sense amplification function for amplifying the outputs of the memory cells in the same column as the memory cell 1₀₁, and controls output/non-output with the output of the multiplexer 31₁ and the data sequence switching signal 131 as well as its inversion signal.

Reference numeral 21ₙ₋₁ denotes a buffer circuit which has a sense amplification function for amplifying the outputs of the memory cells in the same column as the memory cell 1₀ₙ₋₁, and controls output/non-output with the output of the multiplexer 31ₙ₋₁ and the data sequence switching signal 131 as well as its inversion signal (by the inverter 132).

Reference numeral 22₁ denotes a buffer circuit which has a sense amplification function for amplifying the outputs of the memory cells in the same column as the memory cell 2₀₀, and controls output/non-output with the output of a 2-input AND gate 52₀.

Reference numeral 22₁ denotes a buffer circuit which has a sense amplification function for amplifying the outputs of the memory cells in the same column as the memory cell 2₀₁, and controls output/non-output with the output of the multiplexer 32₁ and the data sequence switching signal 131 as well as its inversion signal.

Reference numeral 22ₙ₋₁ denotes a buffer circuit which has a sense amplification function for amplifying the outputs of the memory cells in the same column as the memory cell 2₀ₙ₋₁, and controls output/non-output with the output of the multiplexer 32ₙ₋₁ and the data sequence switching signal 131 as well as its inversion signal.

Reference numeral 23₀ denotes a buffer circuit which has a sense amplification function for amplifying the outputs of the memory cells in the same column as the memory cell 3₀₀, and controls output/non-output with the output of a 2-input AND gate 53₀.

Reference numeral 23₁ denotes a buffer circuit which has a sense amplification function for amplifying the outputs of the memory cells in the same column as the memory cell 3₀₁, and controls output/non-output with the output of the multiplexer 33₁ and the data sequence switching signal 131 as well as its inversion signal.

Reference numeral 23ₙ₋₁ denotes a buffer circuit which has a sense amplification function for amplifying the outputs of the memory cells in the same column as the memory cell 3₀ₙ₋₁, and controls output/non-output with the output of the multiplexer 33ₙ₋₁ and the data sequence switching signal 131 as well as its inversion signal.

The multiplexer 30₁ is selectively controlled by the data sequence switching signal 131, and outputs the output of the 2-input AND gate 50₁ when the data sequence switching signal 131 is L level, and outputs the output of the 2-input AND gate 50₀ when the signal 13 is H level.

Likewise, the multiplexer 30ₙ₋₁ is selectively controlled by the data sequence switching signal 131, and outputs the output of the 2-input AND gate 50ₙ₋₁ when the data sequence switching signal 131 is L level, and outputs the output of the 2-input AND gate 50₀ when the signal 13 is H level.

While the construction for performing readout control for the memory cell array 1₀ is described above, similar constructions are provided for the other memory cell arrays 1₁ to 1₃.

That is, the multiplexer 31₁ is selectively controlled by the data sequence switching signal 131, and outputs the output of the 2-input AND gate 51₁ when the data sequence switching signal 131 is L level, and outputs the output of the 2-input AND gate 51₀ when the signal 13 is H level.

The multiplexer 31ₙ₋₁ is selectively controlled by the data sequence switching signal 131, and outputs the output of the 2-input AND gate 51ₙ₋₁ when the data sequence switching signal 131 is L level, and outputs the output of the 2-input AND gate 51₀ when the signal 13 is H level.

The multiplexer 32₁ is selectively controlled by the data sequence switching signal 131, and outputs the output of the 2-input AND gate 52₁ when the data sequence switching signal 131 is L level, and outputs the output of the 2-input AND gate 52₀ when the signal 13 is H level.

The multiplexer 32ₙ₋₁ is selectively controlled by the data sequence switching signal 131, and outputs the output of the 2-input AND gate 52ₙ₋₁ when the data sequence switching signal 131 is L level, and outputs the output of the 2-input AND gate 52₀ when the signal 13 is H level.

The multiplexer 33, is selectively controlled by the data sequence switching signal 131, and outputs the output of the 2-input AND gate 53₁ when the data sequence switching signal 131 is L level, and outputs the output of the 2-input AND gate 53₀ when the signal 13 is H level.

The multiplexer 33ₙ₋₁ is selectively controlled by the data sequence switching signal 131, and outputs the output of the 2-input AND gate 53ₙ₋₁ when the data sequence switching signal 131 is L level, and outputs the output of the 2-input AND gate 53₀ when the signal 13 is H level.

The column selection signals 3₀ and 34₀ are input to the 2-input AND gate 50₀, the column selection signals 3ₙ₋₁ and 34₀ are input to the 2-input AND gate 50ₙ₋₁, the column selection signals 3₀ and 34₁ are input to the 2-input AND gate 51₀, and the column selection signals 3ₙ₋₁ and 34₁ are input to the 2-input AND gate 51ₙ₋₁.

Further, The column selection signals 3₀ and 34₂ are input to the 2-input AND gate 52₀, the column selection signals 3ₙ₋₁ and 34₂ are input to the 2-input AND gate 52ₙ₋₁, the column selection signals 3₀ and 34₃ are input to the 2-input AND gate 53₀, and the column selection signals 3ₙ₋₁ and 34₃ are input to the 2-input AND gate 53ₙ₋₁.

Further, the data sequence switching and outputting unit 101 comprises, like that shown in FIG. 1, buffer circuits 20₀, . . . , 2iᵢ, buffer circuits 20₁, . . . , 20ₙ₋₁, 21₀, 21₂ (not shown), . . . , 21ₙ₋₁, . . . , 2n−1₀, . . . , 2n−1ₙ₋₂, multiplexers 30₁, . . . , 30ₙ₋₁, 31₀, 31₂ (not shown), . . . , 31ₙ₋₁, . . . , 3n−1₀, . . . , 3n−1ₙ₋₂, and 2-input AND gates 50₀, . . . , 53ₙ₋₁.

This data sequence switching and outputting unit 101 outputs either of the data of 1 bits comprising every 1 bit from the memory cell arrays 1₀ to 1₃ constituting the 0th memory cell array group, or data of n bits comprising every 1 bit from the memory cells (e.g., memory cells 0₀₀ to 0₀ₙ₋₁) which belong to the same word of one memory cell array (e.g., memory cell array 1₀) in the 0th memory cell array group, to the data output lines 4₀ to 4ₙ₋₁ according to the data sequence switching signal 131.

Further, the memory cell array selection unit 104 comprises a data sequence switching and outputting unit 201 and 2-input AND gates 50₀ to 53ₙ₋₁, and selects one of the memory cell arrays 1₀ to 1₃ in the 0th memory cell array group.

A description will be given of the operation when performing readout access to the memory address 0.

When H level is input to the word selection signal 2, and the column selection signals 3₀ and 34₀ of the memory block 100 while L level is input to the other word selection signals 2₁, . . . , 2ₘ₋₁ and column selection signals 3₁, . . . , 3ₙ₋₁ and 34₁, 34₂, 34₃, if the data sequence switching signal 131 at this time is L level, the buffer circuit 20₀ outputs the output of the memory cell 0₀₀ to the data output 4₀, and the buffer circuits 20₁, . . . , 20ₙ₋₁, 21₀, . . . , 21ₙ₋₁, 22₀, . . . , 22ₙ₋₁, 23₀, . . . , 23ₙ₋₁ generate no outputs.

By performing similar operations to the respective memory cell arrays corresponding to bit 1 to bit n−1 of the information data, the information data of the memory address 0 can be read to the data outputs 4₀, . . . , 4ₙ₋₁.

Further, when performing readout access to the memory address 0, if the data sequence switching signal 131 is H level, the buffer circuits 20₀, . . . , 20ₙ₋₁ output the outputs of the memory cells 0₀₀, . . . , 0₀ₙ₋₁ to the data outputs 4₀, . . . , 4ₙ₋₁, respectively, and the buffer circuits 21₀, . . . , 21ₙ₋₁, 22₀, . . . , 22ₙ₋₁, 23₀, . . . , 23ₙ₋₁ generate no outputs.

Moreover, when performing readout access to the memory address 1, the buffer circuits 21₀, . . . , 21ₙ₋₁ can output the outputs of the memory cells 1₀₀, . . . , 1₀ₙ₋₁ to the data outputs 4₀, . . . , 4ₙ₋₁, when performing readout access to the memory address 2, the buffer circuits 22₀, . . . , 22ₙ₋₁ can output the outputs of the memory cells 2₀₀, . . . , 2₀ₙ₋₁ to the data outputs 4₀, . . . , 4ₙ₋₁, and when performing readout access to the memory address 3, the buffer circuits 23₀, . . . , 23ₙ₋₁ can output the outputs of the memory cells 3₀₀, . . . , 3₀ₙ₋₁ to the data outputs 4₀, . . . , 4ₙ₋₁, respectively.

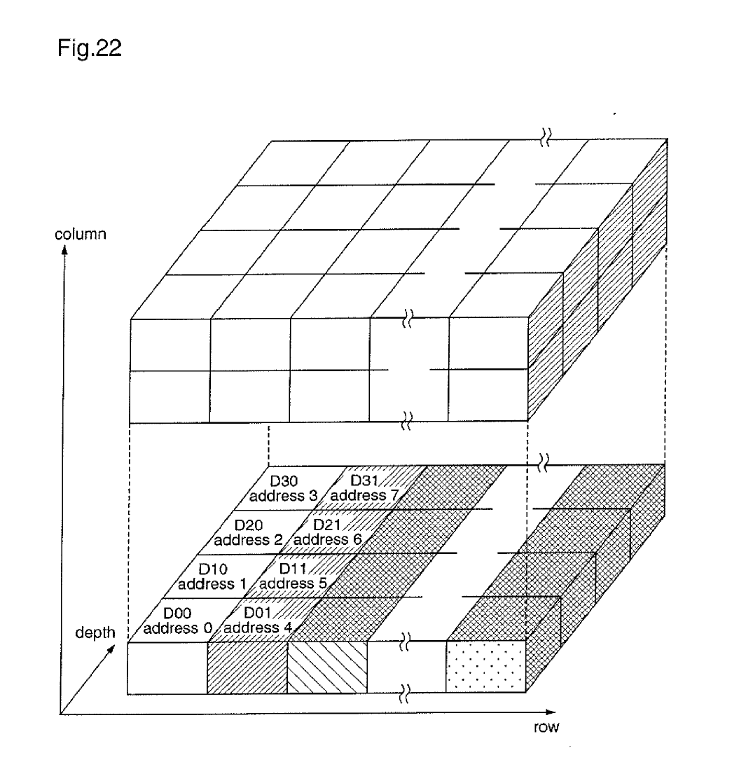

Therefore, when one information data is stored over plural memory addresses and thereby it is necessary to access the logical address space not only in the row and column directions but also in the depth direction as shown in FIG. 22, it is possible to read out only predetermined data bits in the depth direction for each information data unit.

As described above, according to the third embodiment, the memory device is constituted such that, when performing readout from the memory cells constituting the memory cell arrays, it can control as to whether memory cells of the same address in the respective memory cell arrays should be read out or memory cells of all addresses constituting the same row in one memory cell array should be read out, according to the value of the data sequence switching signal. Therefore, when performing readout from the memory cell array that stores information data stored in plural memory addresses, even if it is necessary to access the logical address space not only in the row and column directions but also in the depth direction, it is possible to read out only predetermined data bit in the depth direction for each information data unit, and the memory area for storing redundant data can be reduced by reading out only the predetermined data bits for each information data unit.

### Embodiment 4

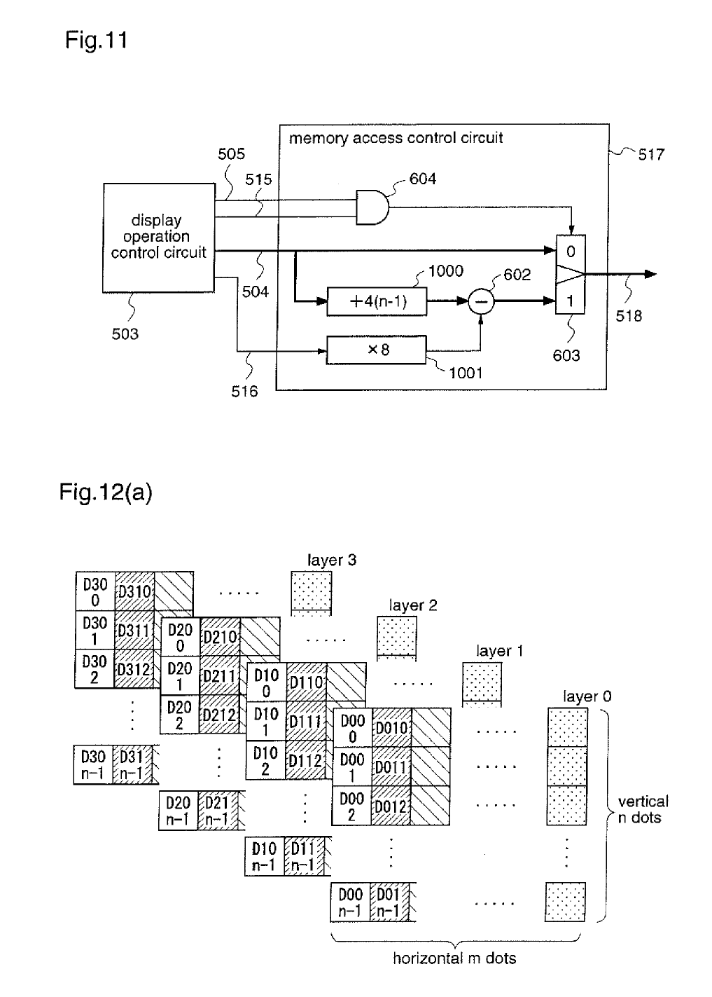

Next, a memory application device according to a fourth embodiment of the present invention will be described with reference to FIG. 11.

FIG. 11 is a block diagram illustrating a schematic construction of a memory access control circuit in a display control device as a memory application device according to the fourth embodiment, and the construction of the display control device is identical to that shown in FIG. 6. Further, a display font ROM 506 has the same construction as that of the memory device according to the third embodiment of the present invention.

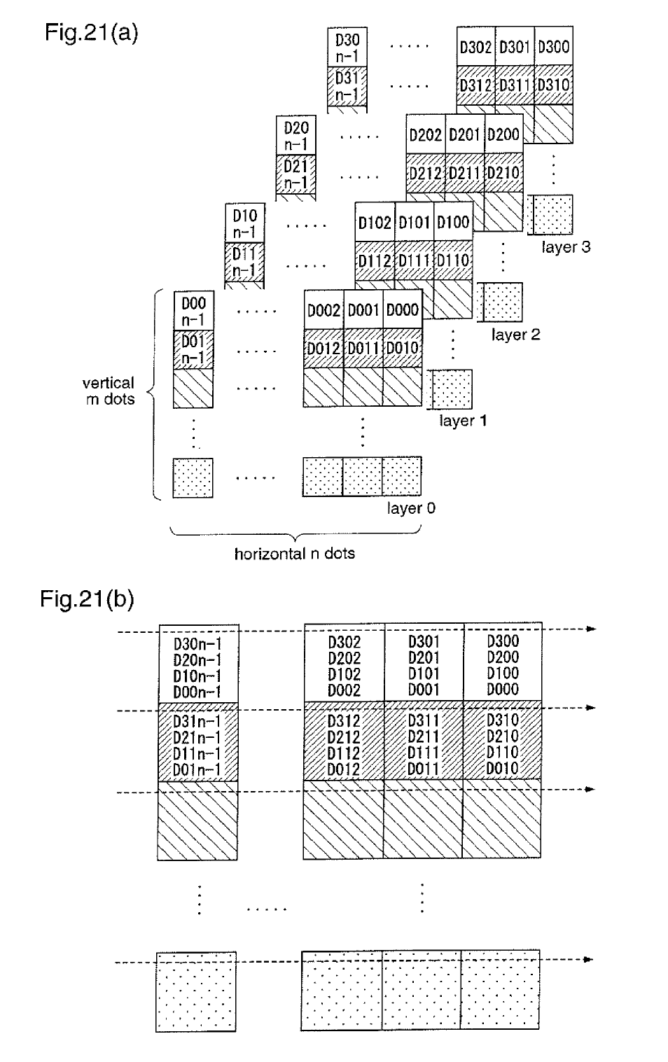

Assuming that 1 dot of the font data is represented by 4-bit data, in FIG. 11, a value of 4×(n−1) is added by the adder 1000 to the display font address 504 inputted to the memory access control circuit 517 according to the number of vertical dots of the font data shown in FIG. 21(a), and a value obtained by octuplicating the horizontal scanning count value 516 with the multiplier 1001 is subtracted by the subtracter 602, and thereafter, the result is input to the selector 603.

The selector 603 outputs the subtraction result as a converted font address 518 only when the 2-input AND gate 604 detects that the display arrangement signal 505 is H level and the display arrangement direction signal 515 is H level. In other cases, the selector 603 outputs the display font address 504 as the converted font address 518.

Accordingly, when the screen is rotated leftward at 90° to be arranged vertically long, the result which is obtained by performing the operation of adding the above-mentioned value of 4×(n−1) and subtracting the value obtained by octuplicating the horizontal scanning count value 516 with the multiplier 1001 can be outputted as the converted font address 518.

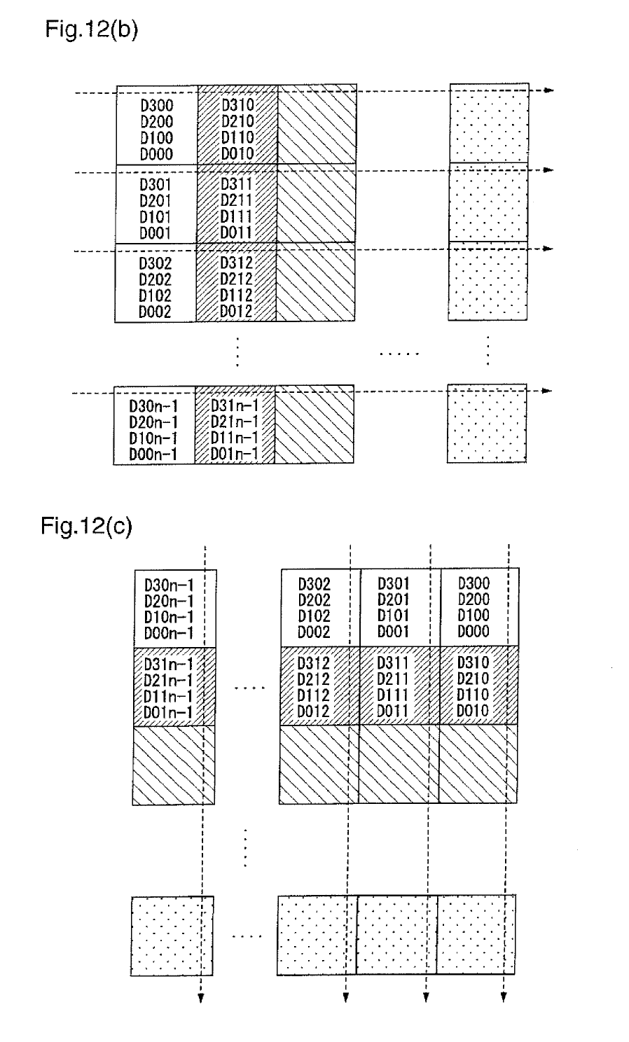

FIG. 12(a) shows the font data in the case where the display 512 is rotated rightward at 90° to be arranged in the vertical direction. The least significant data in layer 0 to layer 3 of the font data shown in FIG. 21(a) are read out with continuous memory addresses to the first line of the font data shown in FIG. 12(a), and further, the arrangement order of the data sequence is inverted from the most significant bit to the least significant bit by the data sequence conversion circuit 513. Therefore, the data of the least significant bit to be read out for the first line of the layer 0 of the font data shown in FIG. 21(a) is read out as the most significant bit, while the data of the least significant bit to be read out for the m-th line of the layer 0 when the font data includes vertical m dots is read out as the least significant bit, simultaneously.

Likewise, the font data corresponding to layer 1, layer 2, and layer 3 are read out and displayed as the first line of the font data shown in FIG. 12(a). FIG. 12(b) shows the state viewed from the direction where the TV screen at this time is normally arranged. When the TV screen of FIG. 12(b) is rotated rightward at 90°, the state shown in FIG. 12(c) is obtained, thereby realizing display of the font data having color representation of gradation colors.

As described above, according to the fourth embodiment, there is provided the display operation control circuit for controlling, when performing readout from the memory cells constituting the memory cell arrays that store layered data, as to whether memory cells of the same address in the respective memory cell arrays should be read out or memory cells of all addresses constituting the same row in one memory cell array should be read out, according to the value of the data sequence switching signal. Therefore, it is possible to provide a memory application device which can reduce the area of the display font ROM without preparing font data for the respective rotation states even when the font data having color representation of gradation colors wherein one dot of the font data is composed of plural bit data are displayed in an application with a TV screen being rotated at 90°.

### Embodiment 5

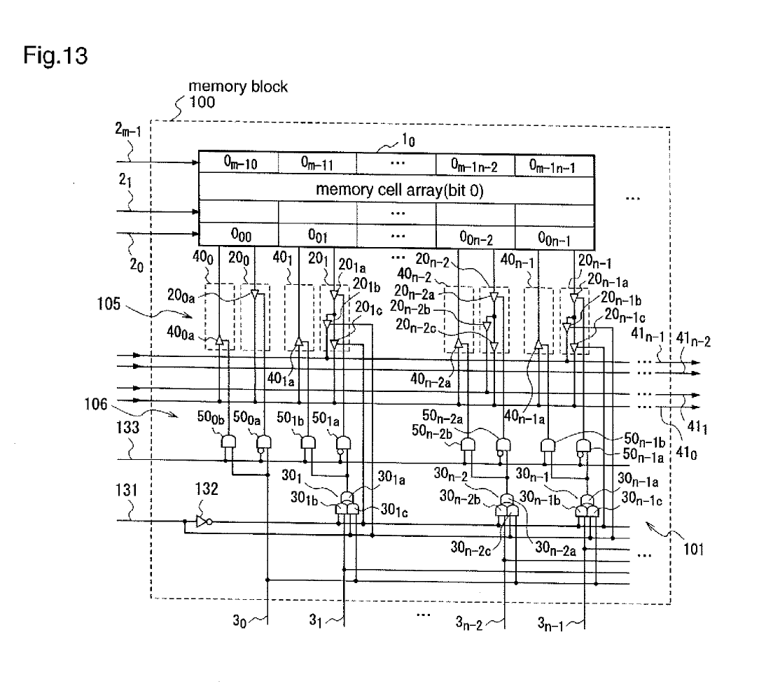

A memory device according to a fifth embodiment of the present invention will be described with reference to the drawings. FIG. 13 is a block diagram illustrating a schematic construction of a memory device according to the fifth embodiment of the present invention.

In FIG. 13, the same reference numerals as those shown in FIG. 1 denote the same or corresponding elements. Reference numeral 100 denotes a memory block, 1₀ denotes a memory cell array, 2₀, . . . , 2ₘ₋₁ denote word selection signals, 3₀, . . . , 3ₙ₋₁ denote column selection signals, 0₀₀, . . . , 0ₘ₋₁ₙ₋₁ denote memory cells, 20₀, . . . , 20ₙ₋₁ denote buffer circuits, 131 denotes a data sequence switching signal, 132 denotes an inverter, and 30₁, . . . , 30ₙ₋₁ denote multiplexers, and these correspond to bit 0 of information data.

Although it is not shown in the figure, similar memory cell arrays 1₁ to 1ₙ₋₁ exist with respect to bit 1 to bit n−1, and they are connected by similar connection relationship as that for bit 0. Further, a word decoder and a column decoder are omitted in the figure.

Hereinafter, the construction of FIG. 13 will be described only for bit 0.

Reference numerals 41₀, . . . , 41ₙ₋₁ denote data inputs/outputs, 40₀, . . . , 40ₙ₋₁ denote input buffers for writing signals of the data inputs/outputs 41₀, . . . , 41ₙ₋₁ into the memory cells 0₀₀, . . . , 0₀ₙ₋₁, 133 denotes a write enabling signal which becomes H level when writing the signals of the data inputs/outputs 41₀, . . . , 41ₙ₋₁ in the memory cells 0₀₀, . . . , 00ₙ₋₁, 50₀b denotes a 2-input AND gate which receives the write enabling signal 133 and the column selection signal 3₀, 50₀a denotes a 2-input AND gate which receives the write enabling signal 133 by negative logic and receives the column selection signal 3₀, 50₁b denotes a 2-input AND gate which receives the write enabling signal 133 and the output of the multiplexer 30₁, 50₁a denotes a 2-input AND gate which receives the write enabling signal 133 by negative logic and receives the output of the multiplexer 30₁, 50ₙ₋₁b denotes a 2-input AND gate which receives the write enabling signal 133 and the output of the multiplexer 30ₙ₋₁, and 50ₙ₋₁a denotes a 2-input AND gate which receives the write enabling signal 133 by negative logic and receives the output of the multiplexer 30ₙ₋₁.

The outputs of the 2-input AND gates 50₀b, . . . , 50ₙ₋₁b are connected as control signals to the input buffers 40₀, . . . , 40ₙ₋₁, and when the outputs of the 2-input AND gates 50₀b, . . . , 50ₙ₋₁b are H level, writing of the signals of the data inputs/outputs 41₀, . . . , 41ₙ₋₁ into the memory cells 0₀₀, . . . , 0₀ₙ₋₁ is permitted, while it is inhibited when they are L level. Further, the outputs of the 2-input AND gates 50₀a, . . . , 50ₙ₋₁a are connected as control signals to the buffer circuits 20₀, . . . , 20ₙ₋₁, and the buffer circuits are controlled to generate no outputs when the write enabling signal 133 is H level.

Further, the data sequence switching and outputting unit 101 has the same construction and performs the same operation as the sequence switching and outputting unit 101 shown in FIG. 1.

A data writing unit 105 comprises the buffer circuits 40₀ to 40ₙ₋₁, and writes data for each column from the data inputs/outputs 41₀ to 41ₙ₋₁ into the memory cells 0₀₀ to 0ₘ₋₁ₙ₋₁ constituting the memory cell array 1₀.

A writing/reading control unit 106 comprises the 2-input AND gates 50₀a to 50ₙ₋₁a and 50₀b to 50ₙ₋₁b, and operates either of the data sequence switching and outputting unit 101 or the data writing unit 105 according to the write enabling signal 133.

The memory block 100 constituted as described above can perform the operation of writing data into the memory cells as well as the readout operation similar to that performed by the memory block according to the first embodiment.

That is, in the memory block 100, when H level is input to the word selection signal 20 and the column selection signal 3₀ and L level is input to the other word selection signals 2₁ to 2ₘ₋₁ and column selection signals 3₁ to 3ₙ₋₁, if the data sequence switching signal 133 at this time is L level and the write enabling signal 131 is H level, the output of the 2-input AND gate 50₀b becomes H level while the outputs of the other 2-input AND gates 50₁b, . . . , 50ₙ₋₁b become L level, whereby the signal of the data input/output 41₀ is written in only the memory cell 0₀₀.

Likewise, by performing the same operation to the memory cell arrays corresponding to bit 1 to bit n−1 of the information data, n-bit information data can be written from the data inputs/outputs 41₀, . . . , 41ₙ₋₁.

Likewise, for the next memory address, H level is input to the word selection signal 2₀ and the column selection signal 3₁ while L level is input to the other word selection signals 2₁, . . . , 2ₘ₋₁ and column selection signals 3₀, 3₂, . . . , 3ₙ₋₁, and the signal of the data input/output 41₁ is written in only the memory cell 0₀₁ when the data sequence switching signal 133 is L level and the write enabling signal 131 is H level.

Next, H level is input to the word selection signal 2₀, the column selection signal 3₀, and the data sequence switching signal 133, and the outputs of the memory cells 0₀₀, . . . , 0₀ₙ₋₁ can be read out as n-bit information data to the data inputs/outputs 41₀, . . . , 41ₙ₋₁ when the write enabling signal 131 is L level, like the memory device according to the first embodiment.

As described above, according to the fifth embodiment, the rewritable memory device is constituted such that, when performing readout from the memory cells constituting the memory cell arrays, it can control as to whether memory cells of the same address in the respective memory cell arrays should be read out or memory cells of all addresses constituting the same row in one memory cell array should be read out, according to the value of the data sequence switching signal. Therefore, it is possible to perform the two different readout operations, i.e., reading memory cells of the same address in the respective memory cell arrays from the same rewritable memory device or reading memory cells of all addresses constituting the same row in one memory cell, and it is not unnecessary to prepare separate memory devices corresponding to these two readout manners, resulting in reductions in the memory capacity and memory area.

### Embodiment 6

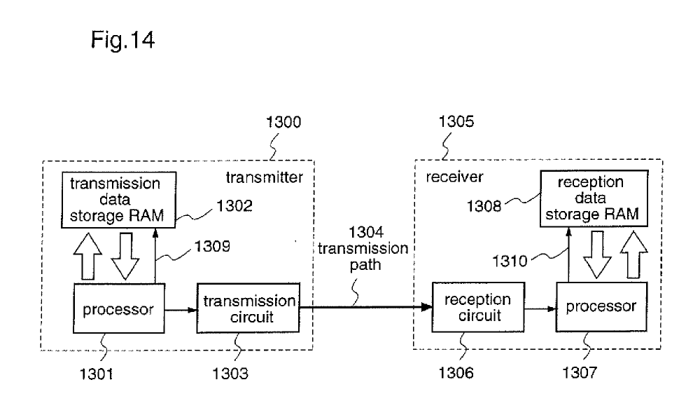

A memory application device according to a sixth embodiment of the present invention will be described with reference to FIG. 14.

FIG. 14 is a block diagram illustrating a schematic construction of a transmission/reception system as a memory application device according to the sixth embodiment.

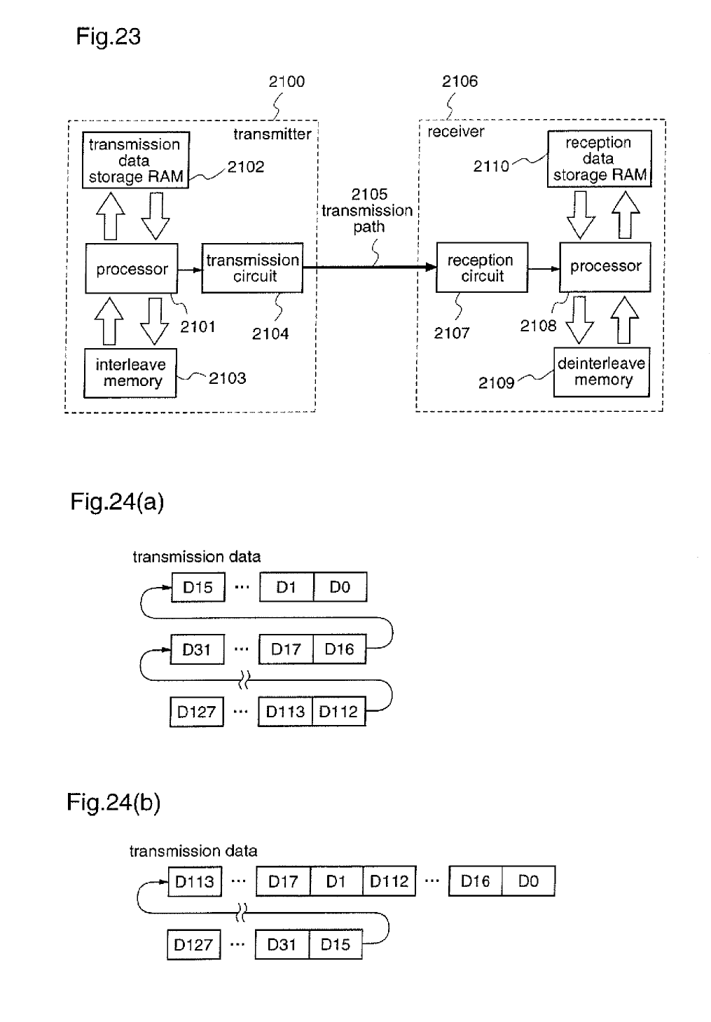

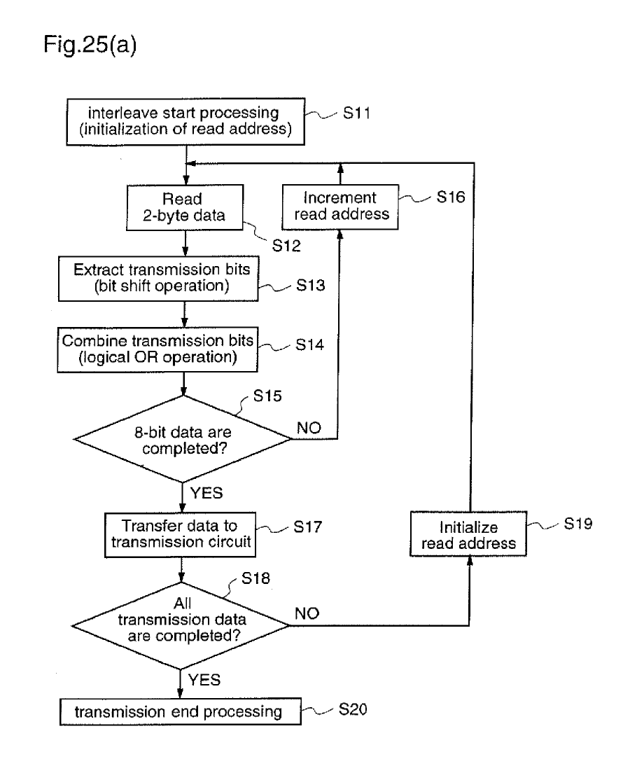

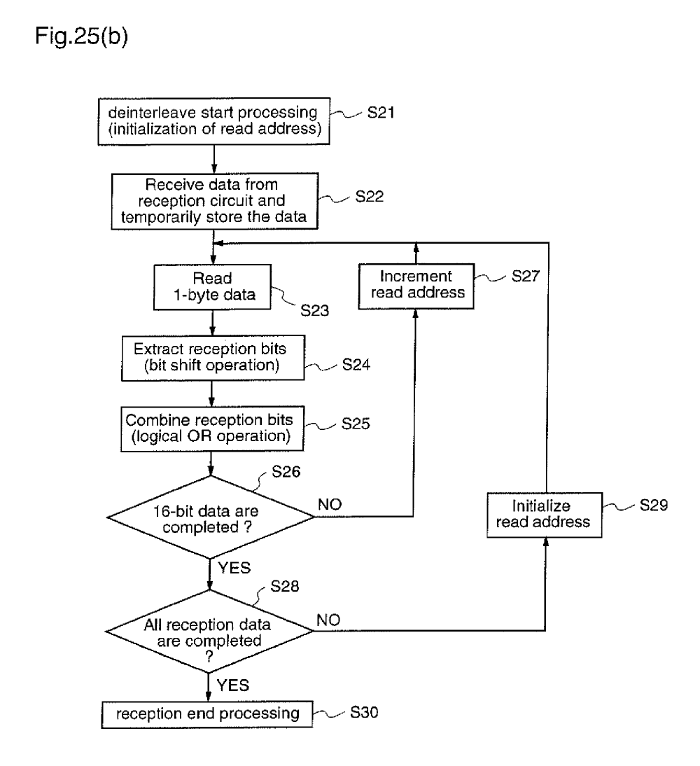

In the transmission/reception system shown in FIG. 14, reference numeral 1300 denotes a transmitter, 1301 denotes a processor, 1303 denotes a transmission circuit, 1304 denotes a transmission path, 1305 denotes a receiver, 1306 denotes a reception circuit, and 1307 denotes a processor, and these are identical to the transmitter 2100, the processor 2101, the transmission circuit 2104, the transmission path 2105, the receiver 2106, the reception circuit 2107, and the processor 2108 shown in FIG. 23, respectively.

Reference numeral 1309 denotes an interleave control signal which is outputted as H level by the processor 1301 when performing interleaving for transmitting transmission data, and becomes L level in other cases. Reference numeral 1310 denotes a deinterleave control signal which is outputted as H level by the processor 1307 when performing deinterleaving for the transmission data, and becomes L level in other cases.

Reference numerals 1302 and 1308 denote a transmission data storage RAM and a reception data storage RAM having the same construction as the memory device according to the fifth embodiment of the present invention, and the interleave control signal 1309 and the deinterleave control signal 1310 are connected to the data sequence switching signal 131 shown in FIG. 13.

In the transmission/reception system constituted as described above, when transmitting the transmission data from the transmitter 1300, the process 1301 previously stores the transmission data in the transmission data storage RAM 1302, and sets the interleave control signal 1309 to H level when reading the transmission data.

At this time, in order to adapt the construction of the memory device shown in FIG. 13 to the interleaving method, the transmission data storage RAM 1302 is constituted such that the number of the memory cells 1201 in the memory cell array 1₀ becomes n when the transmission data are interleaved in n-bit cycle, whereby the transmission data as shown in FIG. 24(a) are converted to the interleaved transmission data as shown in FIG. 24(b) by only being read out from the transmission data storage RAM 1302, and thereafter, only the process of transferring the data to the transmission circuit 1303 is carried out.

When receiving the transmission data by the receiver 1305, the processor 1307 receives the transmission data from the reception circuit 1306 and stores the data in the reception data storage RAM 1308, and sets the deinterleave control signal 1310 to H level when reading out the transmission data.

At this time, if the same RAM as the transmission data storage RAM 1302 corresponding to the interleave method is used for the reception data storage RAM 1308, the same data as the transmission data shown in FIG. 24(a) can be read out as reception data by only reading out the interleaved transmission data shown in FIG. 24(b) from the reception data storage RAM 1308.

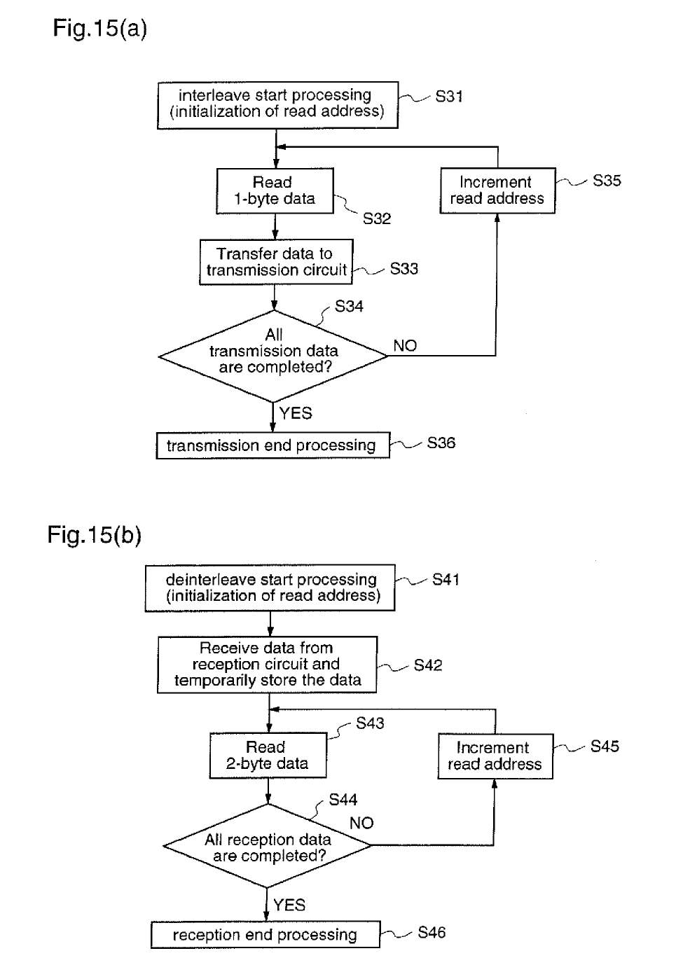

FIG. 15(a) is a flowchart illustrating command steps in the processor 1301 in the transmitter 1300, and FIG. 15(b) is a flowchart illustrating command steps in the processor 1307 in the receiver 1308 shown in FIG. 15(b).

In either case, three or four command steps should be repeated by the number of times that is obtained by dividing the number of all transmission data by the number of data bits that can be read out at one time from the transmission data storage RAM 1302 or the reception data storage RAM 1308, and therefore, the transmission/reception processing can be executed by only performing several tens steps of arithmetic processes.

As described above, according to the sixth embodiment, the transmission data storage RAM of the transmitter and the reception data storage RAM of the receiver are constituted using the memory device according to the fifth embodiment. Therefore, a special memory for interleaving, a memory area for storing interleaved data, a special memory for deinterleaving, and a memory area for storing deinterleaved data can be dispensed with, thereby reducing the area of the memories constituting the transmission/reception system.

### Embodiment 7

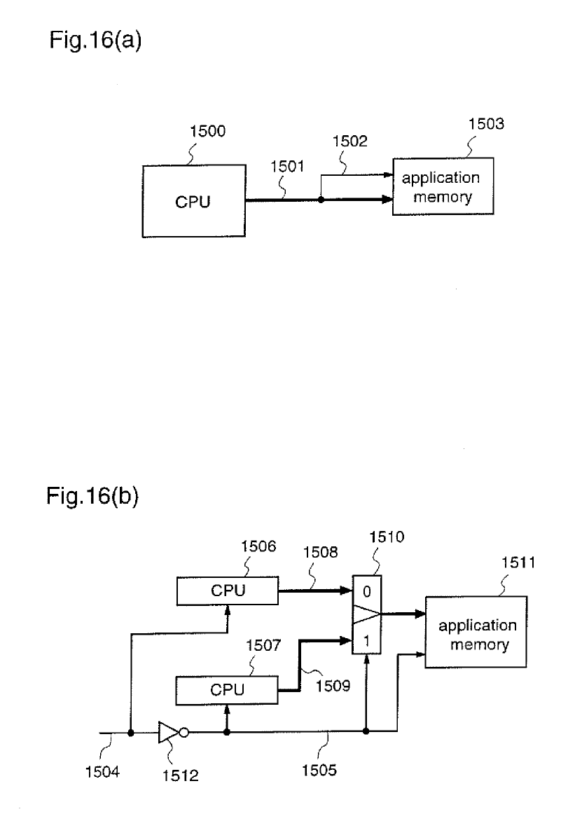

Next, a memory application device according to a seventh embodiment of the present invention will be described with reference to FIG. 16.

FIG. 16(a) is a block diagram illustrating a schematic construction of a processor system using a first CPU in a memory application device according to the seventh embodiment of the present invention.

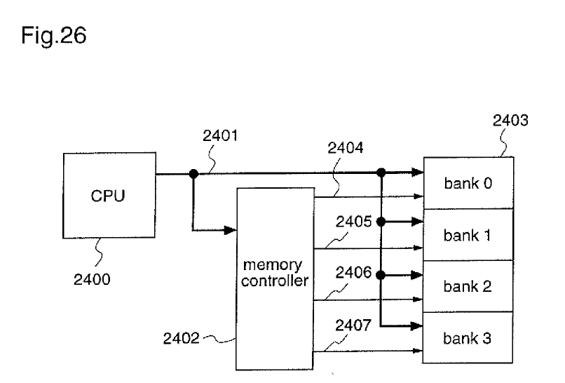

In the processor system using a CPU shown in FIG. 16(a), 1500 denotes a CPU and 1501 denotes an address bus, which are identical to the CPU 2400 and the address bus 2401 of the conventional processor system using a CPU shown in FIG. 26, respectively.

Reference numeral 1502 denotes a higher order address signal of the address bus 1501, and 1503 denotes a program memory having the construction of the memory device according to the first embodiment of the present invention, and the higher order address signal 1502 is connected to the data sequence switching signal 131 shown in FIG. 1.

In order to execute a program, the CPU 1500 inputs the address bus 1501 into the program memory 1503, and reads out a command code stored in the corresponding memory space. Further, command codes of different kinds of programs are divisionally allocated over plural memory addresses to the data bits that are not used as command codes in the memory space where a program or a data table has already been stored.

In order to execute the different kinds of programs, the CPU 1500 performs readout of the command codes from the memory space that is allocated by the higher order address signal 1502. At this time, only predetermined data bits in the memory space where a program or a data table has already been stored are read out by the CPU 1500, and the different kinds of programs are executed, whereby the plural different programs can be executed using the same memory area, resulting in a reduction in the memory size of the program memory 1503.

FIG. 16(b) is a block diagram illustrating a schematic construction of a processor system using first and second CPUs in the memory application device according to the seventh embodiment.

In the processor system using CPUs shown in FIG. 16(b), reference numerals 1506 and 1507 denotes CPUs, 1508 and 1509 denote address buses, and 1511 denotes a program memory, and these are identical to the CPU 1500, the address bus 1501, and the program memory 1503 of the processor system shown in FIG. 16(a), respectively.

Reference numeral 1504 denotes a system clock of the CPU 1506, and 1505 denotes a system clock of the CPU 1507 which is an inversion signal of the system clock 1504, and the CPU 1506 and the CPU 1507 are operated at timings that are different from each other by a half phase of the system clock.

Reference numeral 1510 denotes a selector which selects either of the address buses 1508 and 1509 with the system clock 1505 as a selection signal, and outputs the selected bus to the program memory 1511. The system clock 1505 is connected to the data sequence switching signal 131 shown in FIG. 1. In the program memory 1511, in like manner as shown in FIG. 16(a), command codes of the program stored in the memory space and command code of a program of a kind different from the above-mentioned program are divisionally allocated over plural memory addressed to the predetermined data bits in the same memory space.

In the processor system using the CPU which is constituted as described above, when the system clock 1504 is H level, the address bus 1508 outputted from the CPU 1506 is input to the program memory 1511. At this time, since, L level is input to the data sequence switching signal 131 shown in FIG. 1, the program stored in the memory space is read out and executed.

When the system clock 1504 is L level, the address bus 1509 outputted from the CPU 1507 is input to the program memory 1511. At this time, since H level is input to the data sequence switching signal 131 shown in FIG. 1, the command codes of the different kinds of programs which are divisionally allocated to the predetermined data bits of the plural memory addresses are read out and executed. Therefore, even in the multiprocessor system, the plural different programs can be executed using the same memory area in one program memory, whereby the memory size of the program memory 1511 can be reduced.

As described above, according to the seventh embodiment, the addresses which are respectively outputted from the two CPUs operated with two system clocks whose phases are inverted from each other are switchingly inputted to the application memory. Therefore, a plurality of different programs can be executed by using the same memory area in one program memory, resulting in a reduction in the memory size of the program memory.

While in the first, third, and fourth embodiments the screen is rotated in the clockwise direction, it may be rotated in the counterclockwise direction.

Further, while the case of rotating only one screen is described in the respective embodiments mentioned above, the present invention is also applicable to a case where plural displays are additionally provided in the vertical direction or the horizontal direction or in both directions, with the same effects as described above.

Further, while in the first, third, and fifth embodiments each of the memory cells constituting the memory cell array stores 1 bit, each memory cell may stored plural bits with the same effects as mentioned above.

Further, the memory device according to the third embodiment may be made to perform reading and writing like the memory device of the fifth embodiment, with the same effects as mentioned above.

### APPLICABILITY IN INDUSTRY

As described above, in the present invention, predetermined bit data stored in plural memory addresses are read out as data output from a memory device by accessing predetermined memory addresses, or the data are read out with its sequence being rearranged, whereby reduction in redundant data and effective use of memory area can be achieved, resulting in reduction in memory capacity.

1. A memory device comprising:
a memory circuit having n pieces of memory cell arrays, each memory cell array being constituted by arranging m pieces of memory cells in a column direction and n pieces of memory cells in a word direction (m,n: integers that satisfy m,n≧2) in an array, each memory cell being able to store data of 1 bit, and said n pieces of memory cell arrays being allocated such that data of an i-th bit among data comprising n bits is stored in an i-th memory cell array (i: integer that satisfies 0≦i≦n−1);
a word decoder for simultaneously selecting m pieces of word lines from each of the n pieces of memory cell arrays;
a column decoder for simultaneously selecting n pieces of column lines from each of the n pieces of memory cell arrays; and
a data sequence switching and outputting unit which switchingly outputs either of data of n bits comprising every 1 bit from the respective memory cell arrays that store 0th bit to (n−1)th bit of the n-bit data, or data of n bits obtained from the same word in one of the memory cell arrays which stores one bit among the 0th bit to the (n−1)th bit, to n pieces of data output lines according to a data sequence switching signal.

2. A memory device as defined in claim 1 wherein said data sequence switching and outputting unit includes,
for each of the memory cell arrays corresponding to the bit 0 to the bit n−1,
a j-th multiplexer circuit which outputs either of the i-th output or the j-th output of the column decoder (j: integer that satisfies 0≦j≦n−1 and i≠j) according to the data sequence switching signal;
an i-th buffer circuit which can control as to whether the output of the i-th column line of the memory cell array corresponding to the bit i should be outputted to the i-th data output line or not, according to the i-th output of the column decoder; and
a j-th buffer circuit which can control as to whether the output of the j-th column line of the memory cell array corresponding to the bit i should be outputted or not, according to the output of the j-th multiplexer, and which can select any of the i-th to j-th data output lines to which the output of the j-th column line should be outputted, according to the data sequence switching signal.

3. A memory device as defined in claim 2 wherein
said j-th multiplexer circuit selects the i-th output of the column decoder when the data sequence switching signal is active, and selects the j-th output of the column decoder when the data sequence switching signal is nonactive, and
said j-th buffer circuit outputs the output of the j-th column line to the j-th data line when the data sequence switching signal is active, and to the i-th data line when the data sequence switching signal is nonactive.

4. A memory application device including:
a display font ROM comprising a memory device as defined in claim 1, which stores display data comprising vertical m dots×horizontal n dots, receives a display font address and a display arrangement signal that becomes effective when a display is set in the vertical direction, which is connected to the data sequence switching signal, and outputs display font data corresponding to the display font address and the display arrangement signal; and
a display control device including
a display operation control circuit which controls a display operation on a screen and generates the display font address on the basis of a horizontal sync signal and a vertical sync signal that are supplied from the outside,
a data sequence conversion circuit which receives the display font data, and outputs, as converted font data, the display font data when the display arrangement signal is ineffective, while outputs data obtained by inverting the arrangement order of the data sequence of the display font data from the most significant bit to the least significant bit when the display arrangement signal is effective, and
a display data shift register which receives the converted font data as display data through the display operation control circuit, and shift-outputs the display data.

5. A memory application device as defined in claim 4 further including a memory access control circuit which receives a display arrangement direction signal that becomes effective when a display is rotated leftward at 90° to be arranged in the vertical direction, which signal is generated by the display operation control circuit, a horizontal scanning count value that is reset when horizontal scanning for the 1st line of the font data is started, and stopped in counting when horizontal scanning for the n-th line is completed, and the display font address and the display arrangement signal, and outputs the display font address when either of the display arrangement signal or the display arrangement direction signal is ineffective, while adds n−1 to the display font address and subtracts a value obtained by doubling the horizontal scanning count value from the result of addition, and outputs the resultant value as a converted font address when both of the display arrangement signal and the display arrangement direction signal are effective;
wherein said display font ROM outputs, with the display arrangement signal being connected to the data sequence switching signal, the display font data corresponding to the converted font address and the display arrangement signal; and
said display control unit receives the display font data, and outputs, as converted font data, the display font data when the display arrangement signal is ineffective or the display arrangement direction signal is effective, while outputs data obtained by inverting the arrangement order of the data sequence of the display font data from the most significant bit to the least significant bit when the display arrangement signal is effective and the display arrangement direction signal is ineffective.

6. A memory device comprising:
a memory circuit having n×1 pieces of memory cell arrays (l: integer that satisfies n≧l≧2), each memory cell array being constituted by arranging m pieces of memory cells in a column direction and n pieces of memory cells in a word direction (m,n: integers that satisfy m,n≧2) in an array, each memory cell being able to store data of 1 bit, and said n×1 pieces of memory cell arrays being allocated such that data of an i-th bit among data comprising n bits is stored in an i-th memory cell array group (i: integer that satisfies 0≦i≦l−1) among memory cell array groups each comprising l pieces of memory cell arrays;
a word decoder for simultaneously selecting m pieces of word lines from each of the n×I pieces of memory cell arrays;
a column decoder for simultaneously selecting n pieces of column lines from each of the n×l pieces of memory cell arrays;
a data sequence switching and outputting unit which switchingly outputs either of data of 1 bits comprising every 1 bit from the 0th to (l−1)th memory cell arrays in the i-th memory cell array group, or data of n bits comprising every 1 bit from the same word in one memory cell array among the 0th to (n−1)th memory cell arrays in the i-th memory cell array group, to n pieces of data output lines according to a data sequence switching signal; and
a memory cell array selection unit for selecting one memory cell array from among the 0th to (n−1)th memory cell arrays in the i-th memory cell array group;
wherein the data stored in the memory cell is constituted by data corresponding to 1 pieces of addresses in an address space.

7. A memory device as defined in claim 6 wherein said data sequence switching and outputting unit includes,
for the l pieces of memory cell arrays constituting each memory cell array group,
a j-th multiplexer circuit which outputs either of the i-th output or the j-th output of the column decoder (j: integer that satisfies 0≦j≦n−1 and i≠j) according to the data sequence switching signal;
an i-th buffer circuit which can control as to whether the output of the i-th column line of the memory cell array corresponding to the bit i should be outputted to the i-th data output line or not, according to the i-th output of the column decoder; and
a j-th buffer circuit which can control as to whether the output of the j-th column line of the memory cell array corresponding to the bit i should be outputted or not, according to the output of the j-th multiplexer, and which can select any of the i-th to j-th data output lines to which the output of the j-th column line should be outputted, according to the data sequence switching signal.

8. A memory device as defined in claim 6 wherein said memory cell array selection unit includes,
for the l pieces of memory cell arrays constituting each memory cell array group,
a logic circuit which activates either of the i-th buffer circuit or the j-th multiplexer circuit according to a memory cell array selection signal for selecting one of the 0th to (l−1)th memory cell arrays among the l pieces of memory cell arrays and n pieces of selected outputs from the column decoder.

9. A memory device as defined in claim 6 wherein
said j-th multiplexer circuit selects the i-th output of the column decoder when the data sequence switching signal is active, and selects the j-th output of the column decoder when the data sequence switching signal is nonactive, and
said j-th buffer circuit outputs the output of the j-th column line to the j-th data line when the data sequence switching signal is active, and to the i-th data line when the data sequence switching signal is nonactive.

10. A memory application device including:
a display font ROM comprising a memory device as defined in claim 6, which stores display data comprising vertical m dots×horizontal n dots, receives a display font address and a display arrangement signal that becomes effective when a display is set in the vertical direction, and outputs display font data according to the display font address and the display arrangement signal by using the data sequence switching signal as the display arrangement signal; and
a display control device including
a display operation control circuit which controls a display operation on a screen and generates the display font address on the basis of a horizontal sync signal and a vertical sync signal that are supplied from the outside, and
a memory access control circuit which receives the display arrangement direction signal, the horizontal scanning count value, the display font address, and the display arrangement signal, and outputs the display font address as a converted font address when either of the display arrangement signal or the display arrangement direction signal is ineffective, while outputs a value which is obtained by adding a value of (n−1)×1 to the display font address and subtracting, from the result of addition, a result of multiplication between the horizontal scanning count value and a value of 1×2, when both of the display arrangement signal and the display arrangement direction signal are effective.

11. A memory device comprising:
a memory circuit having n pieces of memory cell arrays, each memory cell array being constituted by arranging m pieces of memory cells in a column direction and n pieces of memory cells in a word direction (m,n: integers that satisfy m,n≧2) in an array, each memory cell being able to rewrite data of 1 bit, and said n pieces of memory cell arrays being allocated such that data of an i-th bit among data comprising n bits is stored in an i-th memory cell array (i: integer that satisfies 0≦i≦n−1);
a word decoder for simultaneously selecting m pieces of word lines from each of the n pieces of memory cell arrays;
a column decoder for simultaneously selecting n pieces of column lines from each of the n pieces of memory cell arrays;
a data sequence switching and outputting unit which switchingly outputs either of data of n bits comprising every 1 bit from the respective memory cell arrays that store 0th bit to (n−1)th bit of the n-bit data, or data of n bits obtained from the same word in one of the memory cell arrays which stores one bit among the 0th bit to the (n−1)th bit, to n pieces of data input/output lines according to a data sequence switching signal;
a data writing unit for writing data inputted from the i-th data input/output line among the n pieces of data input/output lines into the i-th memory cell array among the n pieces of memory cell arrays, respectively; and
a writing/reading control unit for operating either of the data sequence switching and outputting unit or the data writing unit according to a write enabling signal.

12. A memory device as defined in claim 11 wherein said data sequence switching and outputting unit includes,
for each memory cell array,
a j-th multiplexer circuit which outputs either of the i-th output or the j-th output of the column decoder (j: integer that satisfies 0≦j≦n−1 and i≠j) according to the data sequence switching signal;
an i-th buffer circuit which can control as to whether the output of the i-th column line of the memory cell array corresponding to the bit i should be outputted to the i-th data input/output line or not, according to the i-th output of the column decoder; and
a j-th buffer circuit which can control as to whether the output of the j-th column line of the memory cell array corresponding to the bit i should be outputted or not, according to the output of the j-th multiplexer, and which can select any of the i-th to j-th data input/output lines to which the output of the j-th column line should be outputted, according to the data sequence switching signal;
said data writing unit includes
an i-th writing buffer circuit which can control as to whether the data of the i-th data input/output line should be outputted to the i-th column line of the memory cell array corresponding to the bit i; and
said writing/reading control unit includes
an i-th logic gate which outputs the i-th output of the column decoder to either of the data sequence switching unit or the data writing unit according to the write enabling signal, and
a j-th logic gate which outputs the output of the j-th multiplexer to either of the data sequence switching unit or the data writing unit according to the write enabling signal.

13. A memory device as defined in claim 12 wherein
said j-th multiplexer circuit selects the i-th output of the column decoder when the data sequence switching signal is active, and selects the j-th output of the column decoder when the data sequence switching signal is nonactive, and
said j-th buffer circuit outputs the output of the j-th column line to the j-th data line when the data sequence switching signal is active, and to the i-th data line when the data sequence switching signal is nonactive.

14. A memory application device having a transmitter including:
a processor;
a transmission data storage RAM comprising a memory device as defined in claim 11, in which transmission data are stored by the processor, which uses an interleave control signal that is outputted from the processor and becomes effective when the transmission data are read out, as the data sequence switching signal; and
a transmission circuit to which the data read out from the transmission data storage RAM by the processor are transferred.

15. A memory application device having a receiver including:
a processor;
a reception data storage RAM comprising a memory device as defined in claim 11, in which reception data are stored by the processor, which uses a deinterleave control signal that is outputted from the processor and becomes effective when the reception data are read out, as the data sequence switching signal; and
a reception circuit that receives the reception data that are stored in the reception data storage RAM by the processor.

16. A memory application device having a transmission/reception system including:
a transmitter comprising: a processor, a transmission data storage RAM comprising a memory device as defined in claim 11, in which transmission data are stored by the processor, which uses an interleave control signal that is outputted from the processor and becomes effective when the transmission data are read out, as the data sequence switching signal; and a transmission circuit to which the data read out from the transmission data storage RAM by the processor are transferred;
a receiver comprising: a processor, a reception data storage RAM comprising a memory device as defined in claim 11, in which reception data are stored by the processor, which uses a deinterleave control signal that is outputted from the processor and becomes effective when the reception data are read out, as the data sequence switching signal; and a reception circuit that receives the reception data that are stored in the reception data storage RAM by the processor; and
a transmission path connecting the transmitter and the receiver with each other.

17. A memory application device having a processor system including:
a CPU; and
a program memory comprising a memory device as defined in claim 1, which stores programs to be executed by the CPU, receives addresses outputted by the CPU, and uses a higher order address among the addresses as the data sequence switching signal.

18. A memory application device having a processor system including:
a program memory comprising a memory device as defined in claim 1;
a first CPU to which a first system clock signal input;
a second CPU to which a second system clock signal that is obtained by inverting the first system clock signal is input; and
a selection unit which selects an address signal outputted by the first CPU and an address signal outputted by the second CPU, and outputs the selected signal to the program memory;
wherein the address signal outputted by the first CPU is input to the program memory when the first system clock signal is a first logic value, while the address signal outputted by the second CPU is input to the program memory when the first system clock signal is a second logic value.
